(19) United States
(12) Patent Application Publication
(10) Pub. No.: US 2011/0048325 A1
(43) Pub. Date: Mar. 3, 2011

(54) Gas Distribution Apparatus and Substrate Processing Apparatus Having the Same

(76) Inventors: Sun Hong Choi, Gyeonggi-Do (KR); Seung Ho Lee, Gyeonggi-do (KR); Young Hee Lee, Daejeon (KR)

(21) Appl. No.: 12/746,505

(22) PCT Filed: Feb. 26, 2010
(86) PCT No.: PCT/KR2010/001209

§ 371 Date: Jun. 4, 2010

(30) Foreign Application Priority Data
Mar. 3, 2009 (KR) 10-2009-0018083
Aug. 26, 2009 (KR) 10-2009-0079174
Feb. 18, 2010 (KR) 10-2010-0014446

(51) Int. Cl. C23C 16/455; C23C 16/458

(52) U.S. Cl. 118/712; 118/715; 118/724; 118/728

(57) ABSTRACT

Provided are a gas distribution apparatus and a substrate treating apparatus including the same. The substrate treating apparatus includes a chamber comprising a reaction space, a substrate seat unit disposed in the reaction space of the chamber to radially seat a plurality of substrates with respect to a center thereof, and a gas distribution device comprising a first gas distribution part configured to eject at least two source materials onto a substrate through routes different from each other and a second gas distribution part configured to eject a source material having a decomposition temperature greater than an average of decomposition temperatures of the at least two source materials onto the substrate. The first gas distribution part is divided into at least two sections and disposed such that the second gas distribution part is positioned therebetween; and couplable and separable to/from one another.

### BACKGROUND

The present disclosure relates to a substrate processing apparatus, and more particularly, to a substrate processing apparatus including a gas distribution apparatus configured to supply a source material containing two or more elements.

In general, to manufacture semiconductor devices, display devices, and thin film solar batteries, a thin film deposition process for depositing a thin film having a specific material on a substrate, a photolithography process for exposing or covering a selected region of the thin film using a photoresist, and an etching process for removing and patterning the thin film in a selected region are performed. The thin film deposition process and the etching process among the processes are performed within a substrate treating apparatus that is optimized in a vacuum state.

In the substrate treating apparatus, a gas distribution apparatus is used for uniformly distributing a processing gas within a processing chamber having a reaction space. Generally, a chemical vapor phase deposition (CVD) process is performed to deposit the thin film on the substrate. When the CVD process is performed, the gas distribution apparatus may increase in temperature to generate powder or particles due to decomposition and reaction of the processing gas between a lid of the processing chamber and the gas distribution apparatus or within the gas distribution apparatus. For example, when a plurality of process gases is supplied into the processing chamber at the same time to form a compound thin film containing two or more elements is deposited, the plurality of processing gases supplied into the gas distribution apparatus may be reacted with each other within the gas distribution apparatus to generate the particles. The ejection hole of the gas distribution apparatus may be blocked by the particles, or the particles may be adsorbed to the substrate to change device properties.

Thus, the gas distribution apparatus has a multi-layered structure to solve the limitation in which the particles are generated. That is, the inside of the gas distribution apparatus is divided into upper and lower spaces. One processing gas is supplied into the upper space, and the other processing gas is supplied into the lower space to prevent the processing gases from being gas-reacted with each other within the gas distribution apparatus. A plurality of pin type tubes is adequately arranged and the brazing process is performed several times to manufacture the gas distribution apparatus. As the gas distribution apparatus increases in area, the number of tubes increases. Thus, a fail rate may increases when the tubes are coupled using the brazing process. In addition, the brazing process may be repeatedly performed to cause thermal deformation, and a stress is inherent in the brazed portion to cause a leak.

Also, decomposition efficiency may be reduced due to a decomposition temperature difference between the plurality of processing gases, or the processing gas may be decomposed before the processing gas is ejected into the processing chamber. As a result, a thin film deposition speed may be reduced, and uniformity of the thin film may be deteriorated. Also, the usage of the processing gas increases to increase the processing costs. Also, an amount of by-products increases to increase the maintenance and repair costs.

### SUMMARY

The present disclosure provides a gas distribution apparatus in which two or more gases are independently and stably ejected by a first gas distribution plate having a plurality of through holes and manufactured using a drilling or sheet metal forming process and a second gas distribution plate manufactured by coupling a plurality of tubes to each other and including a plurality of nozzles communicating with the plurality of through holes and a substrate treating apparatus including the same.

The present disclosure also provides a gas distribution apparatus in which a temperature measurement unit is disposed on a gas distribution plate including a plurality of ejection nozzles to adjust a refrigerant to an adequate temperature and a substrate treating apparatus including the same.

The present disclosure also provides a gas distribution apparatus in which decomposition efficiency reduction due to a decomposition temperature difference between a plurality of processing gases and decomposition of the processing gas before the processing gas is ejected are prevented and a substrate treating apparatus including the same.

The present disclosure also provides a gas distribution apparatus, which is divided into a plurality of gas distribution apparatuses to couple and separate the gas distribution apparatuses to/from each other and a substrate treating apparatus including the same.

In accordance with an exemplary embodiment, a gas distribution apparatus includes: a first gas distribution part configured to eject at least two source materials onto a substrate through routes different from each other; and a second gas distribution part configured to eject a source material having a decomposition temperature greater than an average of decomposition temperatures of the at least two source materials onto the substrate, wherein the first gas distribution part is divided into at least two sections and disposed such that the second gas distribution part is positioned therebetween; and couplable and separable to/from one another.

The first gas distribution part may include: a first gas distribution plate connected to a first gas inlet tube configured to introduce a first processing gas, the first gas distribution plate including a plurality of first through holes to pass through the first processing gas; a second gas distribution plate connected to a second gas inlet tube configured to introduce a second processing gas, the second gas distribution plate including a plurality of second through holes aligned with the plurality of first through holes to pass through the first processing gas and a plurality of third through holes passing through the second processing gas; and a third gas distribution plate including a plurality of first and second nozzles aligned with the plurality of second and third through holes and configured to respectively eject the first and second processing gases and a space in which a refrigerant flows.

The first gas distribution plate may include: a housing including a space configured to receive the first processing gas supplied from the first gas inlet tube; and a distribution unit disposed within the space, the distribution unit being configured to uniformly distribute the first processing gas introduced from the first gas inlet tube.

The distribution unit may include a plate and a plurality of supply hole defined by punching the plate.

The second gas distribution plate may include: a housing connected to the second gas inlet tube, the housing providing a space configured to receive the second processing gas; a plurality of pillars including the plurality of second through holes in the space; and a plurality of third through holes defined by punching a lower portion of the housing.

The second gas distribution plate may include: a partition disposed within the space; and a buffer space divided by a sidewall of the housing and the partition, the buffer space being configured to receive the second processing gas supplied from the second gas inlet tube.

The second gas distribution plate may include a supply hole in the partition to supply the second processing gas of the buffer space to the space.

The third gas distribution plate may include: a housing in which the plurality of first and second nozzles is disposed, the housing including the space in which the refrigerant flows; and a refrigerant flow tube connected to the housing to supply or discharge the refrigerant.

The housing may include a sidewall surrounding a lateral surface of the space, an upper plate disposed above the sidewall to communicate with the plurality of first and second nozzles, and a lower plate disposed below the sidewall to communicate with the plurality of first and second nozzles.

The housing may include a sidewall surrounding a lateral surface of the space and a lower plate in which the plurality of first and second nozzles directly contacting the second gas distribution plate is disposed.

The gas distribution apparatus may further include a temperature meter disposed on at least one of the second gas distribution plate and the third gas distribution plate.

The second gas distribution part may be disposed at a central portion of a lower side of a chamber lid, and the at least two first gas distribution parts are disposed below the chamber lid such that the second gas distribution part is positioned therebetween.

At least one of the at least two first gas distribution plates is spaced apart from each other.

The gas distribution apparatus may further include at least one third gas distribution part disposed between the at least two first gas distribution parts to eject a fuzzy gas.

The third gas distribution part may eject the fuzzy gas toward an outer side of the substrate.

Protrusions may be formed at both lateral surfaces of the at least two first gas distribution parts, and grooves corresponding to the protrusions are formed at both lateral surfaces of the third gas distribution part to insert protrusions into the grooves, thereby coupling the third gas distribution part between the first gas distribution parts.

A temperature detector may be disposed below the at least one third gas distribution part.

In accordance with another exemplary embodiment, a substrate treating apparatus includes: a chamber including a reaction space; a substrate seat unit disposed in the reaction space of the chamber to radially seat a plurality of substrates with respect to a center thereof; and a gas distribution device including a first gas distribution part configured to eject at least two source materials onto a substrate through routes different from each other and a second gas distribution part configured to eject a source material having a decomposition temperature greater than an average of decomposition temperatures of the at least two source materials onto the substrate, wherein the first gas distribution part is divided into at least two sections and disposed such that the second gas distribution part is positioned therebetween; and couplable and separable to/from one another.

The chamber may include a chamber body in which the reaction space is provided and a chamber lid configured to seal the reaction space, and the first and second gas distribution parts are fixed to the chamber lid.

A refrigerant path through which a refrigerant is circulated may be disposed in the chamber lid.

The first gas distribution part may include: a first gas distribution plate connected to a first gas inlet tube configured to introduce a first processing gas, the first gas distribution plate including a plurality of first through holes to pass through the first processing gas; a second gas distribution plate connected to a second gas inlet tube configured to introduce a second processing gas, the second gas distribution plate including a plurality of second through holes aligned with the plurality of first through holes to pass through the first processing gas and a plurality of third through holes passing through the second processing gas; and a third gas distribution plate including a plurality of first and second nozzles aligned with the plurality of second and third through holes and configured to respectively eject the first and second processing gases, and a space in which a refrigerant flows.

The second gas distribution part may include at least one central injection nozzle disposed in a chamber region corresponding to a central region of the substrate seat unit.

The second gas distribution part may include: a central injection nozzle disposed in a central region of the first gas distribution part; an extension injection nozzle extending into a space between the first gas distribution parts; and an extension path communicating with the central injection nozzle and the extension injection nozzle.

The gas distribution apparatus may further include a path change device disposed in a lower region of the second gas distribution part to eject a processing gas supplied from the second gas distribution part toward the substrate.

The path change device may include: a fixed plate a portion of which is respectively connected to the plurality of first gas distribution parts, the fixed plate being disposed at a centre of the plurality of the first gas distribution parts; an extension path extending from a central region of the fixed plate toward the substrate seat unit; and a path change nozzle disposed at an end region of the extension path.

The gas distribution apparatus may further include a heating unit configured to heat a processing gas ejected from the second gas distribution part or a plasma generation device configured to ionize the processing gas ejected from the second gas distribution part using plasma.

The gas distribution apparatus may further include a protrusion disposed on the substrate seat unit, the protrusion being inserted into a lower side of the second distribution part between the first gas distribution parts.

### BRIEF DESCRIPTION OF THE DRAWINGS

Exemplary embodiments can be understood in more detail from the following description taken in conjunction with the accompanying drawings, in which:

FIG. 1 is a sectional view of a substrate treating apparatus in accordance with an exemplary embodiment;

FIGS. 2 and 3 are a detailed sectional view and an exploded perspective view illustrating a gas distribution apparatus of a substrate treating apparatus in accordance with an exemplary embodiment, respectively;

FIGS. 4A through 4C are sectional views illustrating a process of manufacturing a third gas distribution plate in accordance with an exemplary embodiment;

FIG. 5 is a plan view of a second gas distribution plate in accordance with an exemplary embodiment;

FIG. 6 is an exploded perspective view of a gas distribution apparatus in accordance with another exemplary embodiment;

FIGS. 7A through 7C are sectional views illustrating a process of a third gas distribution plate in accordance with another exemplary embodiment;

FIG. 8 is an exploded perspective view of a gas distribution apparatus in accordance with another exemplary embodiment;

FIG. 9 is a plan view of a substrate seat unit in accordance with another exemplary embodiment;

FIGS. 10 and 11 are a sectional view and a plan view of a substrate treating apparatus in accordance with another exemplary embodiment, respectively;

FIG. 12 a sectional view illustrating a gas distribution apparatus of a substrate treating apparatus in accordance with another exemplary embodiment;

FIG. 13 is a plan view illustrating a gas distribution apparatus of a substrate treating apparatus in accordance with another exemplary embodiment;

FIGS. 14 through 16 are a plan view, an exploded perspective view, and a coupled sectional view of a gas distribution apparatus in accordance with another exemplary embodiment;

FIG. 17 is a plan view of a gas distribution apparatus in accordance with another exemplary embodiment; and

FIGS. 18 through 23 are sectional views of a substrate treating apparatus in accordance with exemplary embodiments.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

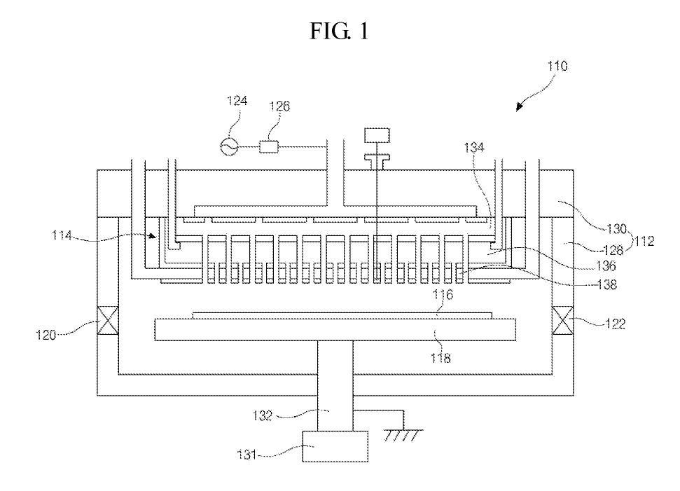

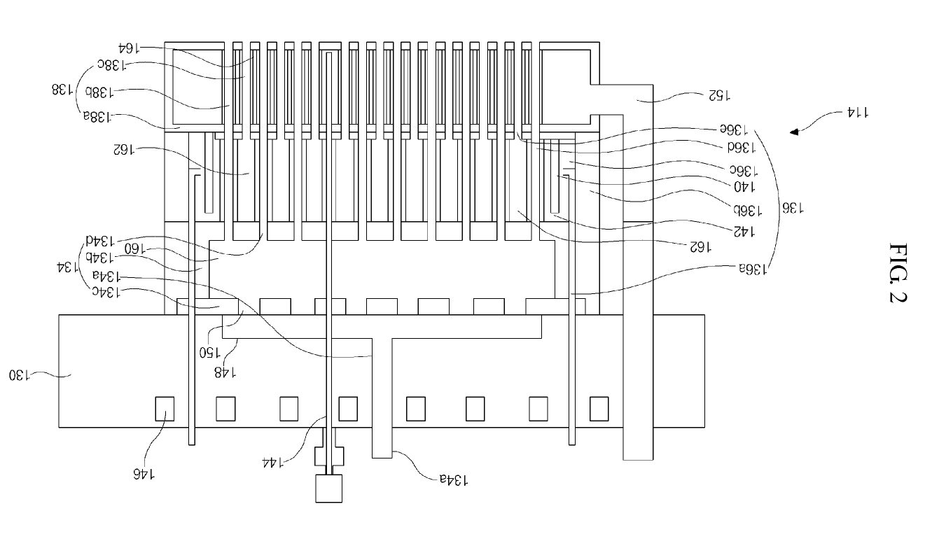

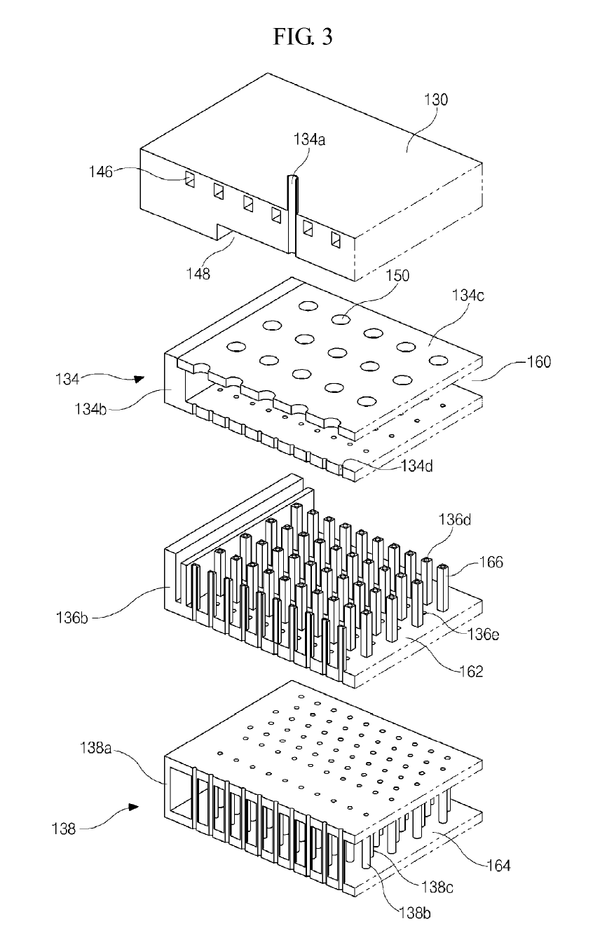

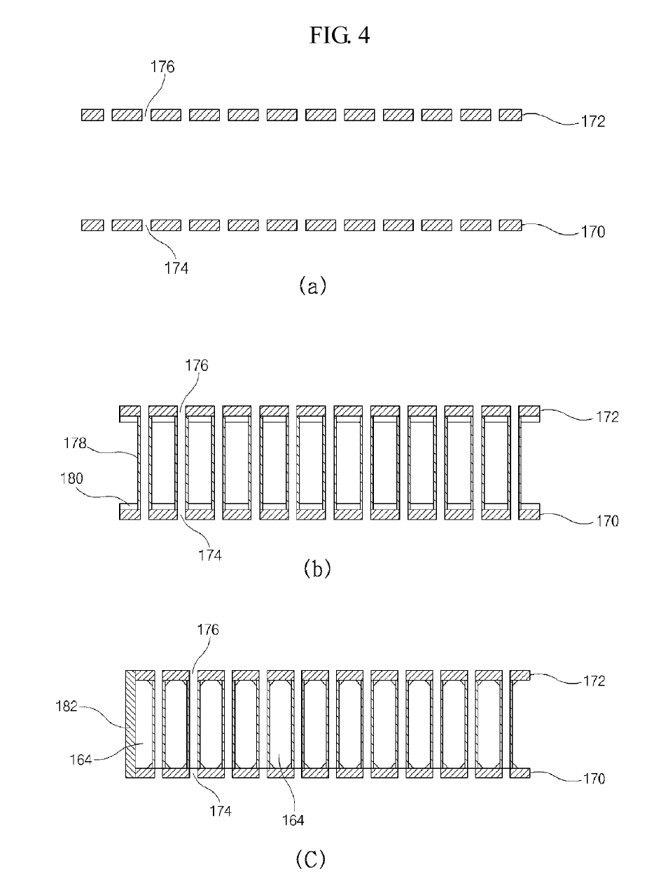

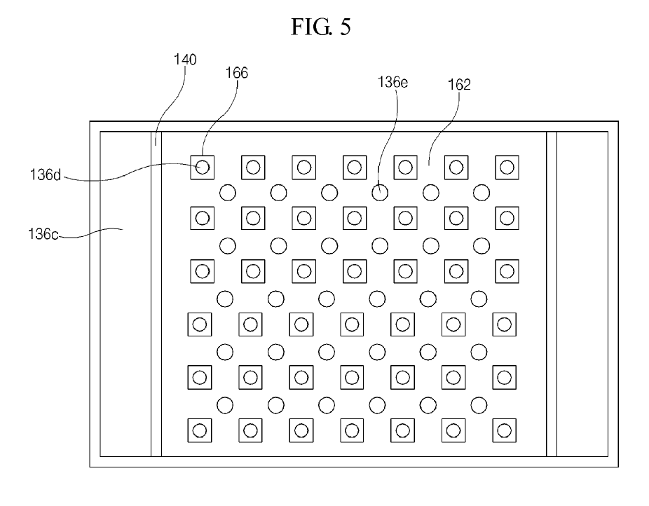

FIG. 1 is a sectional view of a substrate treating apparatus in accordance with an exemplary embodiment, FIGS. 2 and 3 are a detailed sectional view and an exploded perspective view illustrating a gas distribution apparatus of a substrate treating apparatus in accordance with an exemplary embodiment, respectively. FIGS. 4A through 4C are sectional views illustrating a process of manufacturing a third gas distribution plate in accordance with an exemplary embodiment, and FIG. 5 is a plan view of a second gas distribution plate in accordance with an exemplary embodiment.

Referring to FIGS. 1 through 5, a substrate treating apparatus 110 includes a processing chamber 112 providing a reaction space, a gas distribution apparatus 114 disposed at an inner upper portion of the processing chamber 112 to supply processing gases different from each other, a substrate seat unit 118 on which a substrate 116 is seated and facing the gas distribution apparatus 114, a substrate entrance 120 through which the substrate 116 is loaded or unloaded, and a discharge hole 122 through which the processing gases and a by-product within the reaction space are discharged. The gas distribution apparatus 114 is connected to a radio frequency (RF) power source 124. A matcher 126 for an impedance matching may be disposed between the gas distribution apparatus 114 and the RF power source 124. Alternatively, the gas distribution apparatus 114 may not be connected to the RF power source 124 to use a chemical vapor deposition (CVD) method in which the processing gases are simply supplied into the reaction space to form a film.

The processing chamber 112 includes a chamber body 110 and a chamber lid 130 detachably coupled to a chamber body 110 to seal the reaction space. The chamber body 110 has a cylindrical or polygonal shape having an opened upper side. The chamber lid 130 has a plate shape having a shape corresponding to that of the chamber body 110. Although not shown, a sealing member, e.g., an O-ring or a gasket is disposed between the chamber lid 130 and the chamber body 110 to couple the chamber lid 130 to the chamber body 110 using a fixing member. As shown in FIG. 2, a passage 146 in which a refrigerant is circulated as a temperature regulating unit by a refrigerant circulation apparatus (not shown) may be disposed to prevent a temperature of the chamber lid 130 from increasing. Here, the temperature of the chamber lid 130 may increase because a temperature within the reaction space is transmitted to the chamber lid 130 coupled to the gas distribution apparatus 114 when the substrate 116 is treated within the reaction space. That is, the refrigerant may prevent the temperature of the chamber lid 130 from increasing due to the increased temperature of the reaction space while it is circulated into the passage 146 disposed within the chamber lid 30. In addition, it may prevent a temperature of peripheral devices disposed at an upper portion of the camber lid 130 or adjacent to the chamber lid 130 from increasing.

As shown in FIG. 1, the substrate seat unit 118 is supported by a support 132. Also, the substrate seat unit 118 ascends or descends and is rotated by the support 132. The support 132 is connected to a driving unit 131 configured to provide a driving force. A bellows (not shown) for maintaining a sealing and a magnetic thread (not shown) serving as a rotation sealing unit when the support 132 ascends or descends and is rotated are connected between the support 132 and the driving unit 131. The substrate 118 and the substrate 116 have the same configuration as each other. Although the substrate seat unit 118 on which one substrate 116 is seated is illustrated in FIG. 1, the substrate seat unit 118 may include a plurality of susceptors on which the substrate 116 is seated and a disk on which each of the plurality of susceptors is disposed and having a plurality of insertion holes to seat a plurality of substrates 116 thereon.

As shown in FIGS. 2 and 3, the gas distribution apparatus 114 includes a first gas distribution plate 134 receiving a first processing gas to pass through the first processing gas, a second gas distribution plate 136 receiving a second processing gas to pass through the first and second processing gases, and a third gas distribution plate 138 ejecting the first and second processing gases onto the substrate seat unit 118.

The first gas distribution plate 134 includes a first gas inlet tube 134a, a first housing 134b, a baffle 134c, and a plurality of first through holes 134d. The first gas inlet tube 134a passes through a central portion of the chamber lid 130 to introduce the first processing gas. The first housing 134b has a first space 160 receiving the first processing gas. The baffle 134c serves as a distribution unit for uniformly distributing the first processing gas supplied from the first gas inlet tube 134a into the first housing 134b. The plurality of first through holes 134d is disposed on a bottom surface of the first housing 134b to pass through the first processing gas.

The second gas distribution plate 136 includes a second gas inlet tube 136a, a second housing 136b, a buffer space 136c, a plurality of second through holes 136d, and a plurality of third through holes 136e. The second gas inlet tube 136a passes through the chamber lid 130 to introduce a second processing gas. The second housing 136b has a second space 162 receiving the second processing gas. The buffer space 136c is defined by dividing a lateral space of the second housing 136b using a partition 140 and connected to the second gas inlet tube 136a to receive the second processing gas before the second processing gas is supplied into the second space 162. The plurality of second through holes 136d communicates with the plurality of first through holes 134d to pass through the first processing gas. The plurality of third through holes 136e is disposed on a bottom surface of the second housing 136b to pass through the second processing gas. The buffer space 136c is defined in a lateral surface of the second housing 136b. A supply hole 142 is defined in the partition 140 to uniformly supply the second processing gas into the second space 162. The partition 140 is disposed along and inside a sidewall of the second housing 136b and spaced a predetermined distance from the sidewall. The buffer space 136c is defined between the partition 140 and the second housing 136b. The buffer space 136c receives the second processing gas supplied from the second gas inlet tube 136a. The buffer space 136c has a circular or polygonal ring shape in accordance with a configuration of the gas distribution apparatus 114. However, when the second gas inlet tube 136a is provided in plurality and each of the second gas inlet tubes 136a is connected to a lateral surface of the second housing 136b, a plurality of buffer spaces 136c shielded against each other may be defined. Also, the plurality of buffer spaces 136c may communicates with each other. That is to say, when the second gas distribution plate 136 has a square shape, one second gas inlet tube 136a and one buffer space 136 may be disposed and defined at each of four sides. The supply hole 142 defined in the partition 140 may have a successively extending slit shape having the same height or a plurality of openings interruptedly extending to form isolated patterns.

The third gas distribution plate 138 includes a third housing 138a, a plurality of first nozzles 138b, a plurality of second nozzles 138c, and a refrigerant flow tube 152. The third housing 138a has a third space 164 in which a refrigerant flows. The plurality of first nozzles 138b is disposed inside the third housing 138a and respectively communicates with the plurality of second through holes 136d to eject the first processing gas. The plurality of second nozzles 138c communicates with the plurality of third through holes 136e to eject the second processing gas. The refrigerant flow tube 152 is connected to the third housing 138a to circulate the refrigerant. The refrigerant flow tube 152 includes a refrigerant supply tube supplying the refrigerant into the third space 164 and a refrigerant discharge tube discharging the refrigerant within the third space 164. The refrigerant flow tube 152 passes through the chamber lid 130, is inserted into the processing chamber 112, and is connected to a lateral surface of the third housing 138a. The refrigerant is circulated into the refrigerant circulation apparatus (not shown).

When a thin film deposition process is performed on the substrate 116 at a temperature of greater than approximately 1000° C. for a long time in the substrate treating apparatus 110, the gas distribution apparatus 114 may be overheated to a heat resisting temperature or above. Furthermore, the overheating may seriously occur at the third distribution plate 138 of the gas distribution apparatus 114 facing the substrate seat unit 118. Thus, the refrigerant circulation apparatus in which the refrigerant is circulated is disposed inside the third distribution plate 138 as a cooling apparatus for preventing the gas distribution apparatus 114 from overheating. In case of the malfunction of the refrigerant circulation apparatus, a first thermo couple 144 is disposed on the third gas distribution plate 138 to measure a temperature of the gas distribution plate 114. When the gas distribution plate 114 is heated to the heat resisting temperature or above, the heating of the processing chamber 112 is stopped. Also, a second thermo couple (not shown) may be disposed on the second gas distribution plate 136. The first and second thermo couples measure the temperatures of the third and second gas distribution plates 138 and 136, respectively, and compare the temperature of the second gas distribution plate 136 with the third gas distribution plate 138 to adjust the temperature of the refrigerant. When a temperature difference between the second and third gas distribution plates 136 and 138 is large, the plurality of second through holes 136d and the plurality of first nozzles 138b, which communicate with each other and the plurality of third through holes 136e and the plurality of second nozzles 138c, which communicate with each other may be misaligned with each other due to thermal expansion. Thus, the refrigerant may be adjusted to prevent the temperature difference between the second and third gas distribution plates 136 and 138 from being generated. As a result, the misalignment between the plurality of second through holes 136d and the plurality of first nozzles 138b and between the plurality of third through holes 136e and the plurality of second nozzles 138c due to the thermal expansion may be prevented.

Referring to FIGS. 2 and 3, the first gas distribution plate 134 of the gas distribution apparatus 114 is fixed to the chamber lid 130, and the first space 160 receiving the first processing gas introduced through the first gas inlet tube 134a is defined between the chamber lid 130 and the first gas distribution plate 134. A recessed portion 148 is defined in the chamber lid 130 corresponding to the first gas distribution plate 134, and the baffle 134c is disposed between the recessed portion 148 and the first space 160 defined by the first housing 134b. The baffle 134c includes a plate 149 and a plurality of supply holes 150 in which the plate 149 is punched to smoothly supply the first processing gas within the recessed portion 148 into the first space 160. To smoothly supply the first processing gas within the recessed portion 148 into the first space 160, any one of the plurality of supply holes 150 may not match the first gas inlet tube 134a. That is to say, the first processing gas supplied through the first gas inlet tube 134a is reflected by the baffle 134c and received into the recessed portion 148. Then, the first processing gas is supplied into the first space 160 through the plurality of supply holes 150.

The first gas distribution plate 134 is manufactured using aluminum having excellent processability. The inside of the first gas distribution plate 134 is drilled using bulk aluminum to define the first space 160 receiving the first processing gas. Then, a bottom surface of the first space 160 is punched to define the plurality of first through holes 134d for passing through the first processing gas. Alternatively, without using the bulk aluminum, plates formed of aluminum may be coupled to each other using a welding process, and then a lower portion thereof may be punched to define the first gas distribution plate 134. A sidewall of the first housing 134b has a thickness enough to cover the buffer space 136c defined in the second housing 136b of the second gas distribution plate 136. The reason in which the sidewall of the first housing 134b has the thickness enough to cover the buffer space 136c is because the second gas inlet tube 136a connected to the buffer space 136c is inserted through the chamber lid 130 and the sidewall of the first housing 134b. Thus, the sidewall of the first housing 134b may have a thickness equal to the sum of a width of the sidewall of the second housing 136b and a width of the buffer space 136c.

The plurality of first through holes 134d of the first gas distribution plate 134 and the plurality of second through holes 136d of the second gas distribution plate 136 are aligned to communicate with each other, and then, the second gas distribution plate 136 is coupled to the first gas distribution plate 134. The second gas distribution plate 136 is manufactured using aluminum having excellent processability. The second through holes 136d vertically passing through the bulk aluminum is defined, and portions between both ends of the bulk aluminum and between the plurality of second through holes 136d are drilled to define the buffer space 136c and the second space 162 receiving the second processing gas. Then, portions between the plurality of second through holes 136d are punched to define the plurality of third through holes 136e.

Referring to FIGS. 3 and 5, a bottom surface of the bulk aluminum is drilled to maintain a constant thickness to form a plurality of pillars 166 having the second through holes 136d. Lower portions of the plurality of pillars 166 constitute the bottom surface of the second housing 136b in which the plurality of third through holes 136e is defined. Each of the plurality of pillars 166 has an isolated pattern, portions between the plurality of pillars 166 are drilled to define the second spaces 162 communicating with each other. Although each of the plurality of pillars 166 may have a cylindrical shape equal to that of the respective second through holes 136d, the present disclosure is not limited thereto. For example, considering process convenience, each of the pillars 166 may have a square shape as shown in FIG. 5. When each of the plurality of pillars 166 has the square shape, an edge portion of the respective pillars 166 may be rounded so that the second processing gas smoothly flows. The bulk aluminum is drilled to form the sidewall of the second housing 136b in which the second space 162 is defined and the partition 140 dividing the buffer spaces 136c. The partition 140 is processed to define the supply hole 142 through which the second processing gas is supplied at an upper portion of the partition 140. Although one pillar 166 has one second through hole 136d in FIGS. 3 and 5, the present disclosure is not limited thereto. For example, as necessary, one pillar 166 may have two or more second through holes 136d. However, when one pillar 166 has two or more second through holes 136d, since the number of the third through holes 136e is less than that of the second through holes 136d, a relatively large amount of the second processing gas passing through the plurality of first and second through holes 134d and 136d may be supplied when compared to the first processing gas. Thus, the number of the second through hole 136d formed in one pillar 166 may be adjusted in consideration of a supply rate of the first and second processing gases.

The plurality of first through holes 134d of the first gas distribution plate 134 and the plurality of second through holes 136d of the second gas distribution plate 136 are aligned to communicate with each other. When the second gas distribution plate 136 is coupled to the first gas distribution plate 134, a lower portion of the first housing 134b of the first gas distribution plate 134 surface-contacts an upper portion of the plurality of the pillars 166. Thus, the first processing gas is transmitted into the plurality of second through holes 136d of the second gas distribution plate 136 through the plurality of first through holes 134d of the first gas distribution plate 134 while maintaining a sealing of the first processing gas. Here, the second through holes 136d adjacent to one third through hole 136e have the same distance as each other. That is to say, the third through hole 136e is defined at a center of four second through holes 136d. When the second gas distribution plate 136 is coupled to the first gas distribution plate 134, the second gas inlet tube 136a is inserted into the buffer space 136c through the chamber lid 130 and the first gas distribution plate 134. The buffer space 136c and the second space 162 are processed to form the partition 140 between the buffer space 136c and the second space 162, and the second processing gas received into the buffer space 136c is supplied into the second space 162 through the supply hole 142.

The third gas distribution plate 138 is coupled to the second gas distribution plate 136 so that each of the second and third through holes 136d and 136e of the second gas distribution plate 136 communicates with each of the first and second nozzles 138b and 138c of the third gas distribution plate 138. The third gas distribution plate 138 is manufactured using a stainless steel or aluminum having strong heat resistance and corrosion resistance. The third gas distribution plate 138 is manufactured through following processes. As shown in FIG. 4A, first and second plates 170 and 172 formed of a stainless steel are prepared. The first and second plates 170 and 170 are punched to form a plurality of first and second openings 174 and 176 corresponding to the plurality of first and second nozzles 138b and 138c. As shown in FIG. 4B, a plurality of pin type tubes 178 used as the plurality of first and second nozzles 138b and 138c for ejecting the first and second processing gases is prepared. Then, the plurality of tubes 178 is inserted into the first and second openings 174 and 176 and arranged. A paste 180 including a filler metal is coated on the first and second plates 170 and 172 in which the plurality of tubes 178 is arranged. As shown in FIG. 4C, a brazing process is performed to couple the plurality of tubes 178 to the first and second plates 170 and 172, thereby forming the plurality of first second nozzles 138b and 138c for ejecting the first and second processing gases. The plurality of tubes 178 disposed outside the third space 164 and protruding from the first plate 170 is cut off, and then, a lateral plate 182 formed of a stainless steel is disposed to couple the lateral plate 182 to lateral surfaces between the first and second plates 170 and 172 using welding, thereby forming the third housing 138a having the third space 164 in which the refrigerant flows. The refrigerant flow tube 152 passing through the chamber lid 130 and inserted into a lateral surface of the gas distribution apparatus 114 is connected to the lateral surface of the third housing 138a. A third refrigerant flows to cool the gas distribution apparatus 114.

As shown in FIG. 4B, the plurality of tubes 178 inserted into the plurality of first and second openings 174 and 176 protrude to the outside of the first and second plates 170 and 172. A paste including a filler metal is coated on the first and second plates 170 and 172. That is to say, the paste coated on the first plate 170 is disposed in the third space 164, and the paste coated on the second plate 172 is disposed in the third space 164. As shown in FIG. 4C, the plurality of tubes 178 disposed outside the third space 164 and protruding from the first and second plates 170 and 172 is cut off so that the first and second plates 170 and 172 and the plurality of tubes 178 are flush with each other. Although not shown in FIGS. 4A through 4C, a temperature measurement unit, e.g., a thermo couple may be disposed on the first or second plate 170 or 172 to stop the brazing process when a temperature measured in the brazing process exceeds a reasonable temperature. Although the plurality of pin type tubes is formed using the same material as the first and second plates 170 and 172, the present disclosure is not limited thereto. For example, as necessary, the pin type tubes may be formed using a material different from the first and second plates 170 and 172. The brazing process represents a method in which a filler metal is added to two parent materials to be jointed at a temperature of approximately 450° C. or more to joint the two patent materials to each other at a temperature of less than a melting point. The processing temperature of the brazing process may be changed in accordance with parent materials of objects to be jointed and a type of a paste including a filler metal.

Each of the second and third through holes 136d and 136e of the second gas distribution plate 136 and each of the plurality of first and second nozzles 138b and 138c of the third gas distribution plate 138 are aligned and communicate with each other. When the third gas distribution plate 138 is coupled to the second gas distribution plate 136, a lower portion of the second housing 136b of the second gas distribution plate 136 surface-contacts an upper portion of the third housing of the third gas distribution plate 138. Thus, the first and second processing gases pass through the plurality of second and third through holes 136d and 136e and the plurality of first and second nozzles 138b and 138c and are ejected onto the substrate seat unit 118 while maintaining a sealing of the first and second processing gasses.

Although the gas distribution apparatus 114 is coupled to the chamber lid 130 in FIGS. 2 and 3, the gas distribution apparatus 114 may be disposed spaced from the chamber lid 130. When the chamber 130 is spaced from the gad distribution apparatus 114, a separate rear plate connected to the first gas inlet tube 134a is disposed on an upper portion of the first gas distribution plate 134. Here, the first processing gas may include, for example, trimethylgallium (TMGa), biscyclopentadienylmagnesium (Cp₂Mg), trimethyaluminum (TMAl), and trimethylindium (TMIn), and the second processing gas may include a nitrogen gas such as N₂ and NH₃, a silicon gas such as SiH₄ and SiH₆, and H₂. The gases may be used for forming a light emitting device. For example, when a GaN layer is formed on the substrate 116, TMG may be used as the first processing gas, and NH₃ may be used as the second processing gas.

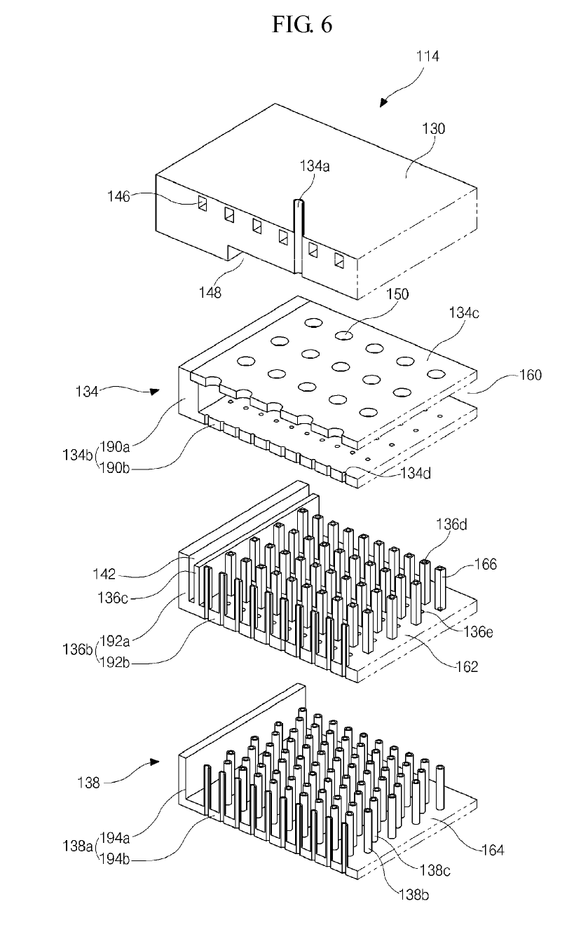

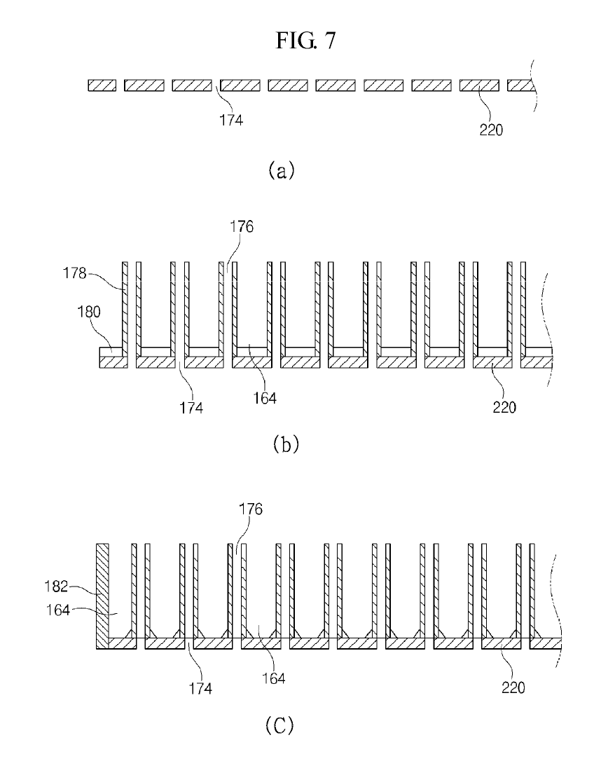

FIG. 6 is an exploded perspective view of a gas distribution apparatus in accordance with another exemplary embodiment, and FIGS. 7A through 7C are sectional views illustrating a process of a third gas distribution plate in accordance with another exemplary embodiment. A gas distribution apparatus in accordance with another exemplary embodiment has the same function as that of the previously described exemplary embodiment. In addition, the gas distribution apparatus in accordance with another exemplary embodiment may be simplified in components to reduce a manufacturing cost. In this exemplary embodiment, the same component as that of the previously described exemplary embodiment is represented by the same reference numeral.

Referring to FIG. 6, a gas distribution apparatus 114 includes a first gas distribution plate 134 receiving a first processing gas to pass through the first processing gas, a second gas distribution plate 136 receiving a second processing gas to pass through the first and second processing gases, and a third gas distribution plate 138 ejecting the first and second processing gases onto a substrate seat unit 118.

The first gas distribution plate 134 includes a first gas inlet tube 134a, a first housing 134b, a baffle 134c, and a plurality of first through holes 134d. The first gas inlet tube 134a passes through a central portion of a chamber lid 130 to introduce the first processing gas. The first housing 134b has a first space 160 receiving the first processing gas. The baffle 134c serves as a distribution unit for uniformly distributing the first processing gas supplied from the first gas inlet tube 134a into the first housing 134b. The plurality of first through holes 134d is defined in a bottom surface of the first housing 134b to pass through the first processing gas. The first housing 134b includes a first sidewall 190a surrounding the first space 160 and a first lower plate 190b disposed below the first sidewall 190a and having the plurality of first through holes 134d.

The second gas distribution plate 136 includes a second gas inlet tube 136a, a second housing 136b, a buffer space 136c, a plurality of second through holes 136d, and a plurality of third through holes 136e. The second gas inlet tube 136a passes through a chamber lid 130 to introduce the second processing gas. The second housing 136b has a second space 162 receiving the second processing gas. The buffer space 136c is defined by dividing a lateral space of the second housing 136b using a partition 140 and connected to the second gas inlet tube 136a to receive the second processing gas before the second processing gas is supplied into the second space 162. The plurality of second through holes 136d communicates with the plurality of first through holes 134d to pass through the first processing gas. The plurality of third through holes 136e is defined in a bottom surface of the second housing 136b to pass through the second processing gas. The second housing 136b includes a second sidewall 192a surrounding a peripheral portion of the second space 162 and a second lower plate 192b disposed below the second sidewall 192a and having the plurality of first and third through holes 134d and 136e. The buffer space 136c is defined in a lateral surface of the second housing 136b. A supply hole 142 is defined in the partition 140 to uniformly supply the second processing gas into the second space 162. The partition 140 is disposed along the sidewall 192a of the second housing 136b and spaced a predetermined distance from the sidewall 192a. The buffer space 136c is defined between the partition 140 and the second housing 136b. The buffer space 136c receives the second processing gas supplied from the second gas inlet tube 136a. The buffer space 136c has a circular or polygonal ring shape in accordance with a configuration of the gas distribution apparatus 114. However, when the second gas inlet tube 136a is provided in plurality and each of the second gas inlet tubes 136a is connected to the sidewall 192a of the second housing 136b, a plurality of buffer spaces 136c shielded against each other may be defined. Also, the plurality of buffer spaces 136c may communicates with each other. That is to say, when the second gas distribution plate 136 has a square shape, one second gas inlet tube 136a and one buffer space 136 may be disposed and defined at each of four sides. The supply hole 142 defined in the partition 140 may have a successively extending slit shape having the same height or a plurality of openings interruptedly extending to form isolated patterns.

The third gas distribution plate 138 includes a third housing 138a, a plurality of first nozzles 138b, a plurality of second nozzles 138c, and a refrigerant flow tube (now shown). The third housing 138a has a third space 164 in which a refrigerant flows. The plurality of first nozzles 138b is disposed inside the third housing 138a and respectively communicates with the plurality of second through holes 136d to eject the first processing gas. The plurality of second nozzles 138c communicates with the plurality of third through holes 136e to eject the second processing gas. The refrigerant flow tube is connected to the third housing 138a to circulate the refrigerant. The third housing 138a includes a third sidewall 194a surrounding the third space 164 and a third lower plate 194b disposed below the third sidewall 194a and including the first and second nozzles 138b and 138c. The refrigerant flow tube includes a refrigerant supply tube supplying the refrigerant into the third space 164 and a refrigerant discharge tube discharging the refrigerant within the third space 164. The refrigerant flow tube passes through the chamber lid 130, is inserted into the processing chamber 112, and is connected to the third sidewall 194a of the third housing 138a. The refrigerant is circulated into the refrigerant circulation apparatus (not shown).

The third gas distribution plate 138 is manufactured through following processes. As shown in FIG. 7A, a plate 220 formed of a stainless steel or aluminum is prepared. The pate 220 is punched to form a plurality of first and second openings 174 and 176 corresponding to the plurality of first and second nozzles 138b and 138c. As shown in FIG. 7B, a plurality of pin type tubes 178 used as the plurality of first and second nozzles 138b and 138c for ejecting the first and second processing gases is prepared. Then, the plurality of tubes 178 is inserted into the plurality of first and second openings 174 and 176 and arranged. A paste 180 including a filler metal is coated on the plate 222 in which the plurality of tubes 178 is arranged. As shown in FIG. 7C, a brazing process is performed to couple the plurality of tubes 178 to the first and second plates 170 and 172, thereby forming the plurality of first second nozzles 138b and 138c for ejecting the first and second processing gases. A lateral plate 182 formed of a stainless or aluminum is disposed to allow the third space 164 to surround the third space 164 and to be connected a circumference portion of the plate 220, and then the plate 220 and the lateral plate 182 are coupled to each other using welding to form the third housing 138a having the third space 164 in which the refrigerant flows. The refrigerant flow tube passing through the chamber lid 130 and inserted into a lateral surface of the gas distribution apparatus 114 is connected to the lateral surface of the third housing 138a. A third refrigerant flows to cool the gas distribution apparatus 114.

In another exemplary embodiment, the third housing 138a of the third gas distribution plate 138 does not include an upper plate. The third housing 138a includes the third sidewall 194a and the third lower plate 194b. Thus, the plurality of tube type first and second nozzles 138b and 138b communicating with the plurality of second and third through holes 136d and 136e directly contact the second lower plate 192b of the second housing 136b constituting the second gas distribution plate 136. Since each of the plurality of first and second nozzles 138b and 138c has a tube shape having a certain thickness, upper portions of the plurality of first and second nozzles 138b and 138c surface-contact a lower portion of the second lower plate 192b. Thus, another exemplary embodiment, the third gas distribution plate 138 may be manufactured through a relatively simple process when compared to that of the previously described exemplary embodiment.

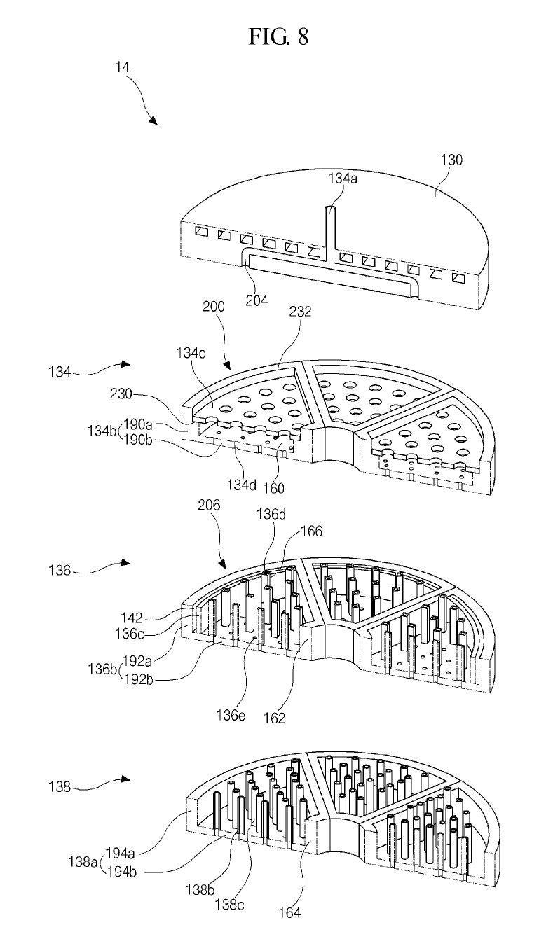

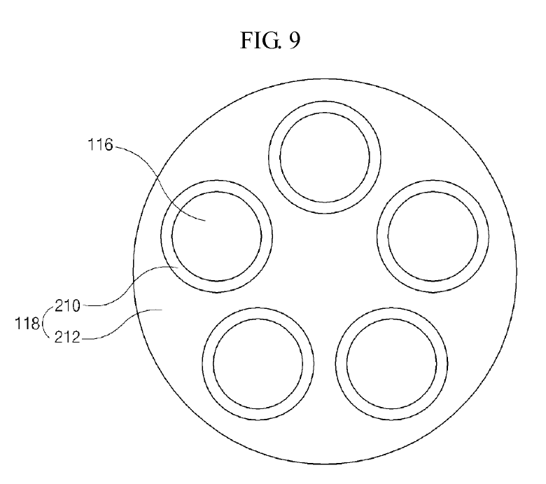

FIG. 8 is an exploded perspective view of a gas distribution apparatus in accordance with another exemplary embodiment, and FIG. 9 is a plan view of a substrate seat unit in accordance with another exemplary embodiment. In this exemplary embodiment is different from the previously described exemplary embodiments in that first and third gas distribution plates are divided when a gas distribution apparatus is large-scaled. In this exemplary embodiment, the same component as those of the previously described exemplary embodiments is represented by the same reference numeral.

Referring to FIG. 8, a gas distribution apparatus 144 includes a first gas distribution plate 134 receiving a first processing gas to pass through the first processing gas, a second gas distribution plate 136 receiving a second processing gas to pass through the first and second processing gases, and a third gas distribution plate 138 ejecting the first and second processing gases onto a substrate seat unit (not shown) of a processing chamber.

The first gas distribution plate 134 includes a first gas inlet tube 134a, a first housing 134b, a baffle 134c, and a plurality of first sub gas distribution plates 200. The first gas inlet tube 134a passes through a chamber lid 130 to introduce the first processing gas. The first housing 134b has a first space 160 receiving the first processing gas. The baffle 134c serves as a distribution unit for uniformly distributing the first processing gas supplied from the first gas inlet tube 134a into the first housing 134b. The plurality of first sub distribution plates 200 includes a plurality of first through holes 134d defined in a bottom surface of the first housing 134b to pass through the first processing gas.

Each of the first sub gas distribution plates 200 has a shape varied in accordance to that of the processing chamber. In this exemplary embodiment, the first sub gas distribution plate 200 has a fan shape and an end of the first sub gas distribution plate 200 adjacent to a central portion of the first gas distribution plate 134 has an arc shape so that the first sub gas distribution plate 200 is adequate for a case in which a cylindrical processing chamber is used and a plurality of circular wafers as substrates is stacked and processed. When the plurality of first sub gas distribution plates 200 is combined to assemble the first gas distribution plate 134, a circular shape having a hollow is formed at a central portion thereof.

As shown in FIG. 9, in case where a wafer is used as a substrate and a plurality of substrates 116 is stacked on a substrate seat unit 118, the substrate seat unit 118 includes a plurality of susceptors on which the substrates 116 are seated and a disk 212 on which the plurality of susceptors 210 is disposed. When the first gas distribution plate 134 has a circular shape, the plurality of sub gas distribution plates 200 is divided by a plurality of straight lines passing through a center of the first gas distribution plate 134. Here, the plurality of first sub gas distribution plates 200 has the same size. When the first gas distribution plate 134 includes six first sub gas distribution plates 200, each of the first sub gas distribution plates 200 adjacent to a central portion of the first gas distribution plate 134 has an angle of approximately 60°. When the first gas distribution plate 134 has a square shape, the first sub gas distribution plate is divided into a plurality of square shapes having the same size as each other.

The first housing 134b includes a first sidewall 190a surrounding a first space 160 and a first lower plate 190b disposed below the first sidewall 190a and having a plurality of first through holes 134d. As shown in FIG. 9, the plurality of susceptors 210 is not disposed at a central portion of the disk 212. Thus, since the substrate 116 is not seated on the central portion of the disk 212, a substrate treating process is not affected even through the first gas distribution plate 134 has the hollow at the central portion thereof. Also, since the end of the respective first sub gas distribution plates 200 has the arc shape to form the hollow at the central portion of the first gas distribution plate 134, the first sub gas distribution plate 200 may be easily manufactured and assembled. When the end of the first sub gas distribution plate 200 extends up to the central portion of the processing chamber, it may be difficult to uniformly form the plurality of first through holes 134d in the first lower plate 190b of the first housing 134b corresponding to the end of the first sub gas distribution plate 200.

A first gas inlet tube 134a is branched into a plurality of sub gas inlet tubes 204 to supply the first processing gas into the first space 160 of each of the plurality of first sub gas distribution plates 200. One or more first sub gas inlet tubes 204 are uniformly connected to the first sub gas distribution plate 200. The first sub gas inlet tube 204 may be buried into the chamber lid 130 to supply the first processing gas at the central portion of the first sub gas distribution plate 200, or the first sub gas inlet tube 204 may be branched from the first gas inlet tube 134a to the first sub gas inlet tube 204 at the outside of the processing chamber and then the first sub gas inlet tube 204 may pass through the chamber lid 130 to supply the first processing gas into the first space of the first sub gas distribution plate 200.

Unlike the previously described exemplary embodiments, in this exemplary embodiment, a recessed portion 148 may not be disposed in the chamber lid 130. A stepped portion 230 is disposed along an inner circumference of the sidewall 190a of the first housing 134b. When the baffle 134c is disposed at the stepped portion 230, a receiving space 232 receiving the first processing gas supplied from the first sub gas inlet tube 204 is defined above the baffle 134c within the first housing 134b. The baffle 134c uniformly supplies the first processing gas within the receiving space 232 into the first space 160.

The second gas distribution plate 136 includes a second gas inlet tube (see reference numeral 136a of FIG. 1), a second housing 136b, a buffer space 136c, a plurality of second through holes 136d, and a plurality of second sub gas distribution plates 206. The second gas inlet tube 136a passes through the chamber lid 130 to introduce a second processing gas. The second housing 136b has a second space 162 receiving the second processing gas. The buffer space 136c is defined by dividing a lateral space of the second housing 136b using a partition 140 and connected to the second gas inlet tube 136a to receive the second processing gas before the second processing gas is supplied into the second space 162. The plurality of second through holes 136d communicates with the plurality of first through holes 134d to pass through the first processing gas. The plurality of second sub gas distribution plates 206 includes a plurality of third through holes 136e defined in a bottom surface of the second housing 136b to pass through the second processing gas.

The second sub gas distribution plate 206 has the same shape as the first sub gas distribution plate 200. Thus, like the first sub gas distribution plate 200, the second sub gas distribution plate 206 has a fan shape, and an end of the second sub gas distribution plate 206 adjacent to a central portion of the second gas distribution plate 136 has an arc shape. Also, when the plurality of second sub gas distribution plates 206 is assembled to assemble the second gas distribution plate 136, the second gas distribution plate 136 has a circular shape having a hollow at a central portion thereof. The second housing 136b includes a second sidewall 192a surrounding a peripheral portion of the second space 162 and a second bottom surface 192b disposed below the second sidewall 192a and having the plurality of first and third through holes 134d and 136e. The buffer space 136c is defined in a lateral space of the second housing 136b. A supply hole 142 is defined in a partition 140 to uniformly supply the second processing gas into the second space 162. The partition 140 is disposed along and within the sidewall 192a of the second housing 136b and spaced a predetermined distance from the sidewall 192a. The buffer space 136c is defined between the partition 140 and the second housing 136b. The buffer space 136c receives the second processing gas supplied from the second gas inlet tube 136a. The supply hole 142 defined in the partition 140 may have a successively extending slit shape having the same height or a plurality of openings interruptedly extending to form isolated patterns.

The third gas distribution plate 138 includes a third housing 138a, a plurality of first nozzles 138b, a plurality of second nozzles 138c, and a plurality of sub gas distribution plates 208. The third housing 138a has a third space 164 in which a refrigerant flows. The plurality of first nozzles 138b is disposed inside the third housing 138a and respectively communicates with the plurality of second through holes 136d to eject the first processing gas. The plurality of second nozzles 138c communicates with the plurality of third through holes 136e to eject the second processing gas. The plurality of sub gas distribution plates 208 includes a refrigerant flow tube connected to the third housing 138a to circulate the refrigerant. The third housing 138a includes a third sidewall 194a surrounding the third space 164 and a third lower plate 194b disposed below the third sidewall 194a and including the first and second nozzles 138b and 138c. The refrigerant flow tube includes a refrigerant supply tube supplying the refrigerant into the third space 164 and a refrigerant discharge tube discharging the refrigerant within the third space 164. The refrigerant flow tube passes through the chamber lid 130, is inserted into the processing chamber 112, and is connected to a lateral surface of the third housing 138a. The refrigerant is circulated into the refrigerant circulation apparatus (not shown).

The third sub gas distribution plate 208 has the same shape as the first and second sub gas distribution plates 200 and 206. Thus, like the first and second sub gas distribution plates 200 and 206, the third sub gas distribution plate 208 has a fan shape, and an end of the third sub gas distribution plate 208 adjacent to a central portion of the third gas distribution plate 138 has an arc shape. Also, when the plurality of third sub gas distribution plates 208 is assembled to assemble the third gas distribution plate 138, the third gas distribution plate 138 has a circular shape having a hollow at a central portion thereof. The third housing 138b includes a third sidewall 194a surrounding a peripheral portion of the third space 164 and a third lower plate 194b disposed below the third sidewall 194a and including the plurality of first and second nozzles 138b and 138c.

In this exemplary embodiment, the third housing 138a of the third gas distribution plate 138 includes the third sidewall 194a and the third lower plate 194b. Also, the plurality of tube type first and second nozzles 138b and 138b communicating with the plurality of second and third through holes 136d and 136e directly contact the second lower plate 192b of the second housing 136b constituting the second gas distribution plate 136. As necessary, the third housing 138a may include an upper plate communicating with the plurality of first and second nozzles 138b and 138c. Since each of the plurality of first and second nozzles 138b and 138c has a tube shape having a certain thickness, upper portions of the plurality of first and second nozzles 138b and 138c surface-contact a lower portion of the second lower plate 192b. Thus, in this exemplary embodiment, the third gas distribution plate 138 may be manufactured through a relatively simple process when compared to that of the previously described exemplary embodiment.

A gas distribution apparatus 114 in accordance with another exemplary embodiment may eject at least portion of a plurality of processing gases onto direct upper regions of substrate 116 and supply a processing gas having a high decomposition temperature of the plurality of processing gases into a space (e.g., a central upper region of a substrate seat unit 118) between the plurality of substrates 116. In this case, the plurality of substrates 116 may be seated on the substrate seat unit 118 and radially disposed with respect to a center of the substrate seat unit 118. Thus, the processing gas having the high decomposition temperature may be supplied into a region having the highest temperature of a chamber lid region to improve decomposition efficiency. The gas distribution apparatus 114 in accordance with another exemplary embodiment and a substrate treating apparatus including the same will be described below. Descriptions of duplicate parts with the foregoing exemplary embodiments are omitted.

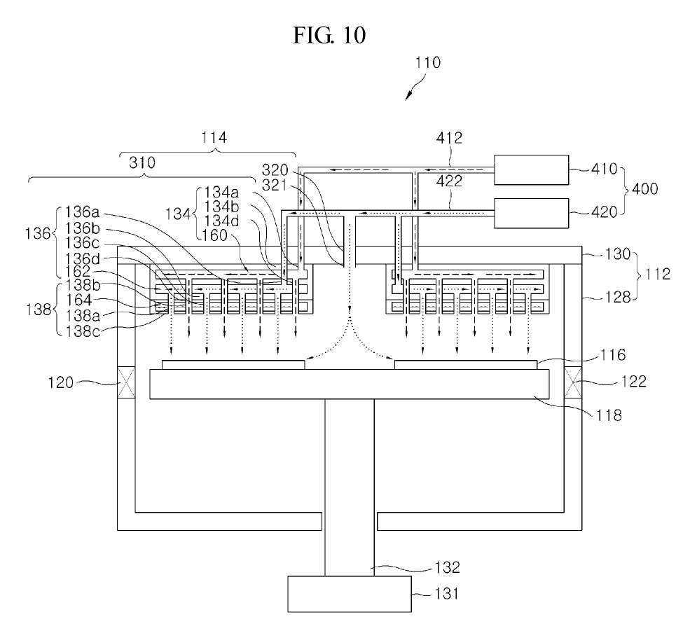

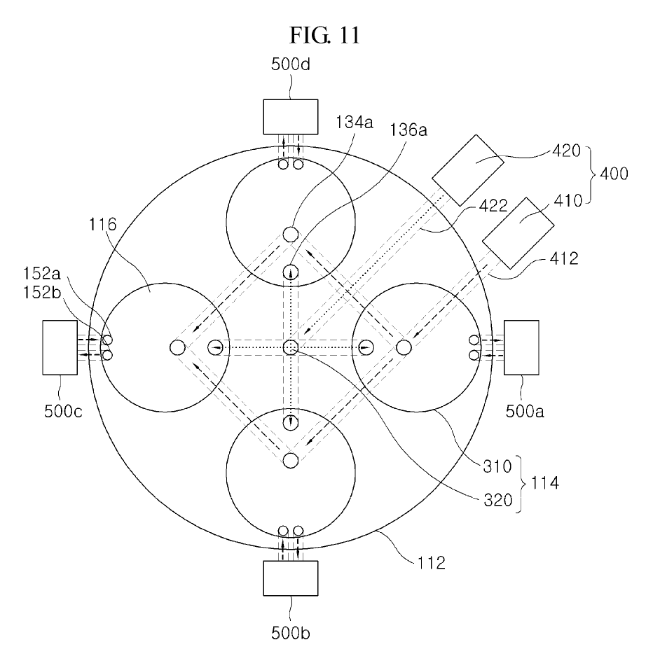

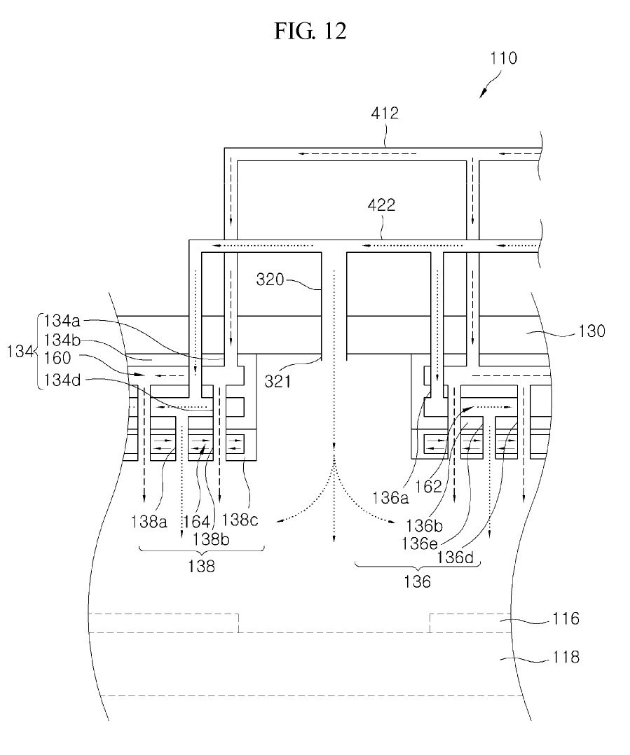

FIGS. 10 and 11 are a sectional view and a plan view of a substrate treating apparatus in accordance with another exemplary embodiment, respectively, and FIG. 12 a sectional view illustrating a gas distribution apparatus of a substrate treating apparatus in accordance with another exemplary embodiment.

Referring to FIGS. 10 and 12, a substrate treating apparatus in accordance with this exemplary embodiment includes a processing chamber 112 providing a reaction space, a substrate seat unit 118 disposed in the reaction space of the processing chamber 112 to seat a substrate 116, and a gas distribution apparatus 114 disposed in the reaction space of the processing chamber 112 to supply processing gases different from each other. Also, the gas distribution apparatus 114 includes first and second gas distribution parts 310 and 320. Here, the first gas distribution part 310 is provided in plurality. Each of the plurality of first gas distribution parts 310 includes first, second, and third gas distribution plates 134, 136, and 138, which are stacked with each other.

In the gas distribution apparatus 114 in accordance with this exemplary embodiment, the first gas distribution part 310 supplies at least portion of a plurality of processing gases onto direct upper regions of the substrate 116. Also, the second gas distribution part 320 supplies supply a processing gas having a high decomposition temperature of the plurality of processing gases into a space (e.g., a central upper region of the substrate seat unit 118) between the plurality of substrates 116. Thus, the processing gas having the high decomposition temperature may be ejected into a region having the highest temperature of a chamber lid region to improve decomposition efficiency. That is, the gas distribution apparatus 114 is disposed on a lower bottom surface of a chamber lid 130, and the processing gas having the high decomposition temperature is supplied to the region having the highest temperature of a region in which the gas distribution apparatus 114 is disposed. Thus, thin film deposition efficiency may be improved, and a non-reacted derelict processing gas may be reduced. An average temperature of decomposition temperatures of the plurality of processing gases may be calculated to supply a processing material having a decomposition temperature greater than the average temperature into the spaces between the plurality of substrates 116. Here, the processing gas having the decomposition temperature greater than the average temperature is referred to as a processing gas having a high decomposition temperature. Also, a processing gas having a decomposition temperature less than the average temperature is cooled and then supplied. Thus, it may prevent the processing gas having the lower decomposition temperature from being decomposed and reacted within the first gas distribution part 310. The gas distribution apparatus 114 includes a processing gas storage part 400 through which the processing gases are supplied. Also, the gas distribution apparatus 114 further includes a refrigerant storage part 500 through which a refrigerant for cooling the processing gases is supplied.

An apparatus configured to deposit two binary compound on the substrate using two processing gases described below will be mainly described. That is, first and second processing gas storage parts 410 and 420 are provided to eject first and second processing gases within the first and second processing gas storage parts 410 and 420 onto the substrate 116, respectively. Here, the first and second processing gas storage parts 410 and 420 may store a material having a gaseous state and a material having a liquid state. For convenience, the first and second processing gas storage parts 410 and 420 are called the processing gas storage part 400. Also, this exemplary embodiment is not limited thereto, and a large number of source materials may be used. Here, the first processing gas may include materials such as TMGa, Cp₂Mg, TMAl, and TMIn, and the second processing gas may include a nitrogen gas such as N₂ and NH₃, a silicon gas such as SiH₄ and SiH₆, and H₂.

The first gas distribution part 310 receives the first and second processing gases through first and second gas supply tubes 412 and 422 to supply the first and second processing gases to the substrate 116 through separated spaces (or routes). The first gas distribution part 310 cools the first and second processing gases to supply the cooled first and second processing gases. The first gas distribution part 310 includes a first gas distribution plate 134, a second gas distribution plate 136, and a third gas distribution plate 138. The first gas distribution plate 134 receives the first processing gas of the first gas storage part 410 through the first gas supply tube 412 to supply the first processing gas. The second gas distribution plate 136 receives the second processing gas of the second gas storage part 420 through the second gas supply tube 422 to supply the second processing gas. The third gas distribution plate 138 cools the supplied processing gases. Here, the first, second, and third gas distribution plates 134, 136, and 138 are vertically stacked with each other. As shown in FIG. 10, the third gas distribution plate 138 may be disposed between the first and second gad distribution plates 134 and 136 and the substrate seat unit 118 to prevent the processing gases within the first and second gas distribution plates 134 and 136 from being decomposed due to heat of the substrate seat unit 118. As described above, each of the gas distribution plates may be variously varied in accordance with the number of processing gases.

The first gas distribution plate 134 includes a first gas inlet tube 134a, a first housing 134b, and a plurality of first through holes 134d. The first gas inlet tube 134a passes through a chamber lid 130 to introduce the first processing gas. The first housing 134b has a first space 160 receiving the first processing gas. The plurality of first through holes 134d extends from the first housing 134b to pass through the first processing gas. Also, the first gas distribution plate 134 may further include a baffle (not shown) uniformly distributes the first processing gas into the first housing 134b. The second gas distribution plate 136 includes a second gas inlet tube 136a, a second housing 136b, a plurality of second through holes 136d, and a plurality of third through holes 136e. The second gas inlet tube 136a passes through the chamber lid 130 to introduce the second processing gas. The second housing 136b has a second space 162 receiving the second processing gas. The plurality of second through holes 136d communicates with the plurality of first through holes 134d to pass through the first processing gas. The plurality of third through holes 136e is defined in a bottom surface of the second housing 136b to pass through the second processing gas. The third gas distribution plate 138 includes a third housing 138a, a plurality of first nozzles 138b, and a plurality of second nozzles 138c. The third housing 138a having a third space 164 in which a refrigerant flows. The plurality of first nozzles 138b is disposed inside the third housing 138a and respectively communicates with the plurality of second through holes 136d to eject the first processing gas. The plurality of second nozzles 138c communicates with the plurality of third through holes 136e to eject the second processing gas. Also, the third gas distribution plate 138 further includes a refrigerant flow tube 152 connected to the third housing 138a to circulate the refrigerant. The refrigerant flow tube includes a refrigerant supply tube 152a supplying the refrigerant into the third space 164 and a refrigerant discharge tube 152b discharging the refrigerant within the third space 164. The first through third gas distribution plates 134, 136, and 138 may have the same components as those described with reference to FIGS. 1 through 9.

As described above, the first processing gas supplied into the first space 160 of the first gas distribution plate 134 is supplied into an inner space (i.e., a reaction space) of the processing chamber 112 through the first through hole 136d passing through the second space 162 of the second gas distribution plate 136 and the first nozzle 138d of the third gas distribution plate 138. Also, the second processing gas supplied into the second space 162 of the second gas plate 136 is supplied into an inner space of the processing chamber 112 through the third through hole 136e and the second nozzle 138c of the third gas distribution plate 318.

The first and second processing gases may have temperatures less than that of the substrate seat unit 118 by the refrigerant. Thus, it may prevent the first and second processing gases from being decomposed by heat before the first and second processing gases are ejected into the reaction space of the processing chamber 112. In particular, when a compound thin film containing two or more elements is deposited, two or more source materials having decomposition temperatures different from each other should be used. Thus, when the third gas distribution plate 138 in which the refrigerant is circulated is not used, a processing gas having a relatively lower decomposition temperature in the two or more processing gases is decomposed by heat at the inside (i.e., inner spaces 160 and 162) of the first and second gad distribution plates 134 and 136 due to the heat of the substrate seat unit 118. Thus, thin film deposition efficiency may be significantly reduced to generate particles.

In accordance with this exemplary embodiment, the third gas distribution plate 138 in which the refrigerant is circulated is provided to cool the first and second spaces 160 and 162 of the first and second gas distribution plates 134 and 136 as well as the first and second nozzles 138b and 138c, thereby preventing the processing gases from being decomposed by the heat. However, in this case, since the processing gas having a relatively high decomposition temperature in the two or more processing gases is cooled, the decomposition efficiency may be reduced. In case of the processing gas having the relatively high decomposition temperature, the processing gas is supplied into the reaction space of the processing chamber 112 and then is heated within the reaction space. However, there is a limitation that the processing gas does not have sufficient decomposition efficiency by the heating. Thus, to solve the limitation, a supply amount of the processing gas having the relatively high decomposition temperature should increase. Since the processing gas having the relatively high decomposition temperature is cooled to reduce the decomposition efficiency, the supply amount of the processing gas may increase. Thus, an amount of a non-reacted derelict source material may increase to increase process costs.

As described above, the processing gas having the relatively high decomposition temperature in the two or more processing gases may be ejected into a central region of the substrate seat unit 118 through the second gas distribution part 320 to solve the above-described limitation. That is, in this exemplary embodiment, the first gas distribution part 310 having a plate shape and corresponding to the substrate seat unit 118 is separated into the plurality of first gas distribution parts 310 corresponding to the substrates 116 as shown in FIG. 11. Thus, the first gas distribution part 310 disposed above a central region of the substrate seat unit 180 is removed. That is, the central region of the substrate seat unit 180 is opened toward an upper side (i.e., a chamber lid region). The second gas distribution part 320 ejecting the processing gas having the relatively high decomposition temperature in the two or more processing gases into the upper region of the central portion of the substrate seat unit 118, i.e., a central region of the chamber lid 130 is disposed. The second gas distribution part 320 includes a central ejection nozzle 321 disposed at a position of the chamber lid 130 corresponding to the central region of the substrate seat unit 118. The central ejection nozzle 321 communicates with the second processing gas storage part 420 in which a decomposition temperature is high. Thus, the central ejection nozzle 321 may supply the second processing gas having the relatively high decomposition temperature into the upper region of the central portion of the substrate seat unit 118. Here, the second processing gas supplied into the central region of the substrate seat unit 118 is ejected from a peripheral region of the chamber lid 130 toward the substrate seat unit 118. Then, the second processing gas is moved toward the substrates 116 radially disposed around the central region of the substrate seat unit 118. Thus, the second processing gas has a movement distance greater than that of the second processing gas ejected from the first gas distribution part 310. That is, the second processing gas ejected into the central region of the substrate seat unit 118 is moved into an edge region of the substrate seat unit 118 and exhausted. This is because the second processing gas is exhausted through a lower edge region of the substrate seat unit 118. Here, as the movement distance (i.e., a path) of the processing gas increases, the second processing gas ejected from the second gas distribution part 320 may receive the heat of the substrate seat unit 118 for a longer time. Thus, the second processing gas may be pre-heated by a temperature within a chamber to improve the decomposition efficiency. Furthermore, since separate cooling members are not disposed between the second gas distribution part 320 and the substrate seat unit 118, it may prevent the ejected second processing gas from being cooled.

In this exemplary embodiment, since the processing gas having the relatively high decomposition temperature in the two or more processing gases is additionally supplied into the second gas distribution part 320, the decomposition efficiency may be improved. Thus, a supply amount of the processing gas having the relatively high decomposition temperature may be reduced by about 10% than that of related art. In this exemplary embodiment, the second processing gas of the second gas storage part 420 is supplied into the second gas inlet tube 136a of the second gas distribution plate 136 and the central ejection nozzle 321 of the second gas distribution part 320. Here, a flow controller such as a mass flow controller (MFC) may be disposed at the second gas inlet tube 136a and the central ejection nozzle 321 to vary a flow amount (i.e., supply amount) of the second processing gas. Also, a flow controller may be disposed between the first gas inlet tube 136a of the first gas distribution plate 134 and the first gas storage part 410.

The substrate treating apparatus of this exemplary embodiment is not limited to the above-described descriptions. That is, the substrate treating apparatus may be variously varied. Hereinafter, modified examples of the substrate treating apparatus will be described. The modified examples described below may be mutually applicable to each other.

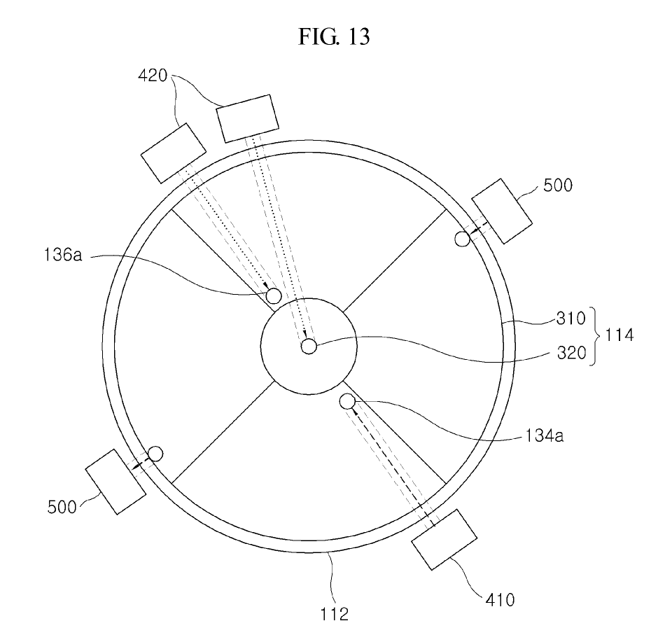

Referring to FIG. 13, a first gas distribution part 310 may be manufactured in one body to cover all substrates 116 disposed on a substrate seat unit 118. Thus, the first gas distribution part 310 may have a ring shape. A second gas distribution part 320 is disposed at a central region of the ring shape. Since the first gas distribution part 310 has the ring shape, the substrate seat unit 118 may be rotated. That is, processing gases may be continuously supplied onto the substrates 116 even through the substrate seat unit 118 is rotated. This is because the first gas distribution part 310 is manufactured in the ring shape corresponding to a rotation radius due to the rotation of the substrate seat unit 118. Thus, since the substrate seat unit 118 is rotated, uniformity of a thin film deposited on the substrate 116 may be improved. Here, as shown in FIG. 13, the first gas distribution part 310 having the ring shape may include a plurality of blocks. When a plurality of large-scaled substrates is seated, the first gas distribution part 310 having the ring shape may increase in diameter. Thus, it may be difficult to manufacture the gas distribution apparatus using a single processing. As shown in FIG. 13, the plurality of first gas distribution parts 310 having an approximately fan shape (four blocks in FIG. 13) may be provided to couple them to each other, thereby manufacturing the first gas distribution part 310 having the ring shape. Here, each of the coupled blocks may be independently operated. Also, as shown in FIG. 13, a processing gas supplied into the first gas distribution part 310 having the ring shape and the second gas distribution part 320 may be supplied through tubes different from each other. Also, the tubes may be connected to storage tanks different from each other.

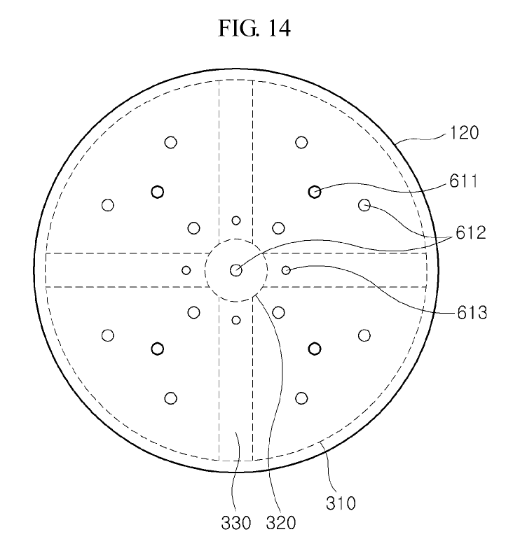

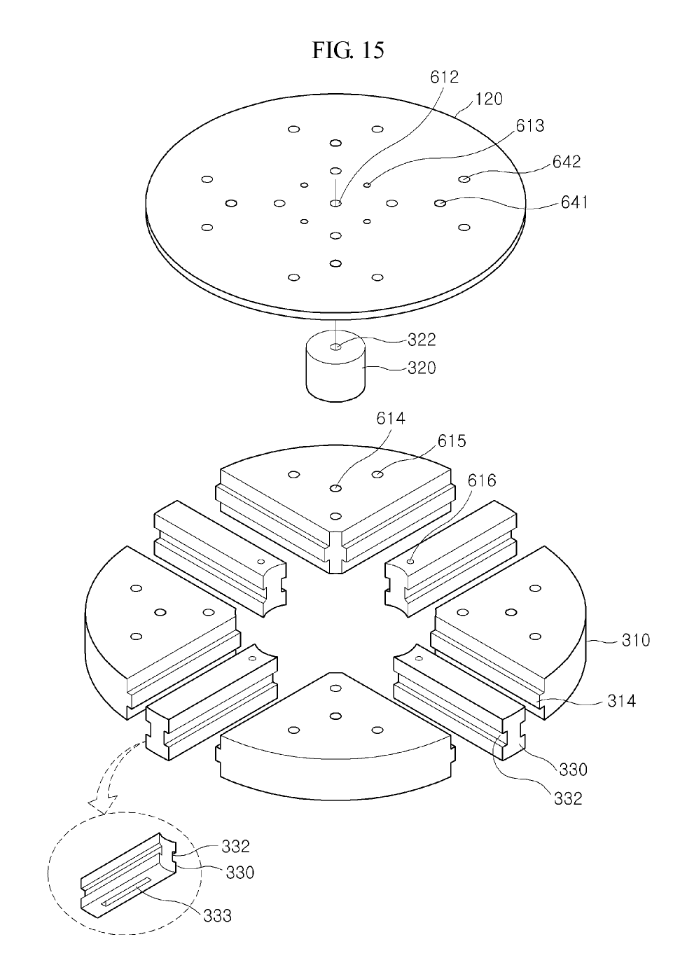

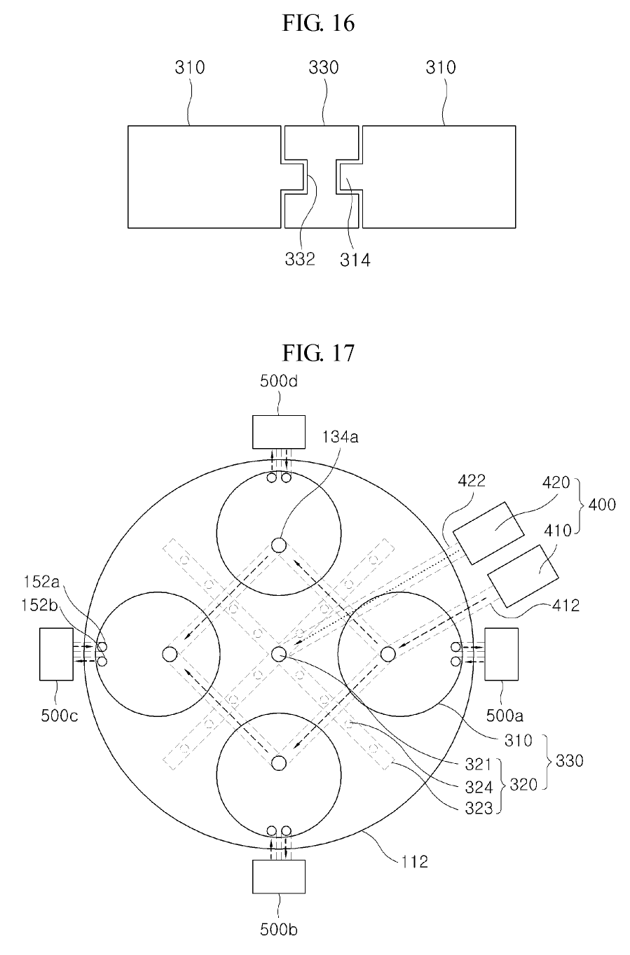

A separable and couplable gas distribution apparatus 114 may be manufactured as shown in FIGS. 14 through 16. Here, FIG. 14 is a plan view of a gas distribution apparatus in accordance with another exemplary embodiment, FIG. 15 is an exploded perspective view of a gas distribution apparatus in accordance with another exemplary embodiment, and FIG. 16 is a coupled sectional view of a gas distribution apparatus in accordance with another exemplary embodiment.

Referring to FIGS. 14 through 16, a gas distribution apparatus 114 in accordance with this exemplary embodiment includes a second gas distribution part 320, a plurality of separable and couplable first gas distribution part 310, and a third gas distribution part 330. The second gas distribution part is disposed at a lower central portion of a chamber lid 130. The plurality of first gas distribution part 310 contacts a lateral surface of the second gas distribution part 320 and is disposed at a lower side of the chamber lid 130. The third gas distribution part 330 is disposed between the plurality of first gas distribution part 310 to supply a fussy gas. That is, in a source material supply part 300 in accordance with this exemplary embodiment, a central ejection part 320 is disposed at the lower central portion of the chamber lid 120, a plurality of source material ejection parts 310 is coupled to the lower side of the chamber lid 120 to contact the central ejection part 320, and a plurality of fuzzy gas injection part is coupled between the plurality of source material ejection parts 310.

Referring to FIGS. 14 and 15, the chamber lid 130 has a shape approximately equal to that of that inside of a chamber body 129, e.g., a circular plate shape with a predetermined thickness. A plurality of inflow holes 611, 612, and 613 vertically passing through the chamber lid 130 is defined in the chamber lid 130. The plurality of inflow holes 611, 612, and 613 are defined in regions respectively corresponding to the second gas distribution part 320, the plurality of first gas distribution parts 310, and the plurality of third gas distribution parts 330. That is, one second inflow hole 612 is defined at a central portion corresponding to the second gas distribution part 320, the first and second inflow holes 611 and 612 are defined at portions corresponding to the plurality of first gas distribution parts 310, and the third inflow hole 613 is defined at a portion corresponding to the plurality of third gas distribution parts 330. Here, one first inflow hole 611 and at least one second inflow hole 612 may be defined at a region corresponding to the first gas distribution part 310. The number of the second inflow hole 612 may be changed in accordance with an inflow rate of the first and second processing gases. For example, three second inflow holes 612 may be defined in one first gas distribution part 310. Also, one first inflow hole 611 and at least one second inflow hole 612 defined in the region corresponding to the first gas distribution part 310 may be arranged with an equal interval in accordance with a configuration of the first gas distribution part 310. That is, one first inflow hole 611 may be defined at a central portion of the region corresponding to the first gas distribution part 310, and at least one, e.g., three second inflow holes 612 may be defined with an equal interval with respect to the first and second inflow holes 611 and 612. The first inflow hole 611 is connected to a first gas supply tube 412 supplying the first processing gas, the second inflow hole 612 is connected to a second gas supply tube 422 supplying the second processing gas, and the third inflow hole 613 is connected to a fuzzy gas supply tube 432 supplying the fuzzy gas. Thus, the second gas distribution part 320 and the first gas distribution part 310 receive the first and second processing gases stored in first and second gas storage parts 410 and 420 from the first and second gas supply tubes 412 and 422 through the first and second inflow holes 611 and 612. Also, the third gas distribution part 330 receives the fuzzy gas from the fuzzy gas supply tube 432 through the third inflow hole 613. The first and second gas supply tubes 412 and 422 may be disposed toward the central portion of the chamber lid 130, branched from the central portion of the chamber lid 130, and connected to the first and second inflow holes 611 and 612. Also, the first and second gas supply tubes 412 and 422 may be branched from the outside of the chamber lid 130 and connected to the first and second inflow holes 612 and 612. Here, a relatively small amount of the first processing gas is introduced to perform a deposition process when compared to an amount of the second processing gas.

The second gas distribution part 320 is disposed at the central portion of the chamber lid 130 and has an approximately cylindrical shape. The second gas distribution part 320 may be integrated with the chamber lid 130. Alternatively, the second gas distribution part 320 and the chamber lid 130 are separately manufactured to couple the second gas distribution part to the chamber lid 130 at the lower central portion of the chamber lid 130. A second gas injection hole 322 corresponding to the second inflow hole 612 of the chamber lid 130 is defined at an upper side of the second gas distribution part 320. Also, at least one injection hole is defined at a lower side of the second gas distribution part 320. Thus, the second gas distribution part 320 receives the second processing gas to eject the second processing gas toward a lower side thereof. Here, the second gas distribution part 320 ejects the second processing gas toward the central portion of the substrate seat unit 118. That is, the second gas distribution part 320 ejects the second processing gas into a central space defined by the plurality of substrates 116 seated on the substrate seat unit 118.

An inner surface of each of the plurality of first gas distribution part 310 contacts the second gas distribution part 320 and is fixed to a lower side of the chamber lid 130. At least two or more first gas distribution parts 320 may be provided. When two first gas distribution parts 320 are provided, each of the two first gas distribution parts 320 has a semicircular shape. When three or more first gas distribution parts 320 are provided, each of the second gas distribution parts 320 has a fan shape in which an inner surface contacting the second gas distribution part 320 has a narrow width and is gradually widened in width toward the outside thereof. Also, when the plurality of first gas distribution part 310 is coupled to the chamber lid 130, the first gas distribution part 310 does not contact an adjacent first gas distribution part 310 and is spaced a predetermined distance from the adjacent first gas distribution part 310. Also, protrusions 314 may be longitudinally disposed on both side surfaces of the first gas distribution part 310. Since the protrusions 314 are provided, the third gas distribution part 330 may be coupled between the first gas distribution parts 310. One first source material injection hole 614 and at least one second source material ejection hole 615 are defined at an upper side of the first gas distribution part 310. One first source material injection hole 614 and at least one second source material injection hole 615 correspond to the first inflow hole 611 and the second inflow hole 612 of the chamber lid 130. Also, as described in the forgoing exemplary embodiments and shown in the drawings, the first gas distribution part 310 includes the first gas distribution plate 134, the second gas distribution plate 136, and the third gas distribution plate 138, which are stacked with each other. The first, second, and third gas distribution plates 134, 136, and 138 are separately manufactured, and then, they are stacked and coupled to each other. That is, the first, second, and third gas distribution plates 134, 136, and 138 may be integrated in one body. Here, since the first, second, and third gas distribution plates 134, 136, and 138 have the same structure and function as those described with reference to the drawings, the structure and function thereof will be omitted.

The third gas distribution part 330 has a bar shape having a predetermined width and thickness and a predetermined space therein. Grooves 332 are longitudinally defined in both side surfaces of the third gas distribution plate 330. The protrusions 314 of the first gas distribution part 310 are inserted into the grooves 332 defined in both side surface of the third gas distribution plate 330. Thus, the third gas distribution part 330 is inserted and coupled between two adjacent first gas distribution parts 310. A fuzzy gas injection hole 616 is defined in an upper side of the third gas distribution part 330 to inject the fuzzy gas through the third inflow hole 613 of the chamber lid 130 and inject the fuzzy gas to the outside of the substrate seat unit 118. To eject the fuzzy gas to the outside of the substrate seat unit 118, an inject hole of the fuzzy gas injection part may be defined in an outer portion of a bottom surface facing a top surface in which the fuzzy gas injection hole 616 is defined or defined in an outer surface facing an inner surface corresponding to the second gas distribution part 320. That is, when the injection hole is defined in the bottom surface, the injection holes may be defined in the bottom surface and a bottom surface disposed on a boundary of the outer surface. Also, a temperature meter 333 may be disposed on at least one third gas distribution part 330, e.g., at least two third gas distribution parts 330 facing each other to measure a temperature within a processing chamber 112. The temperature meter 333 may be disposed on the bottom surface of the third gas distribution part 330. Also, a portion of the third gas distribution part 330 may be recessed, and the temperature meter 330 may be buried into the recessed portion.

In the gas distribution apparatus 114 in accordance with this exemplary embodiment, although four first gas distribution parts 310 and four third gas distribution parts disposed between the four first gas distribution parts 310 are illustrated as an example, the number of the first gas distribution part 310 may be changed in accordance with an inner size of the processing chamber 112 and the number of the substrate 116. Also, since the plurality of first gas distribution parts is separable and couplable, the large-scaled gas distribution apparatus 114 in accordance with the tendency of the large-scaled processing chamber 112 may be further easily manufactured.

As shown in FIG. 17, the second gas distribution part 320 includes a central ejection nozzle 321, an extension ejection nozzle 324, and an extension path 323. The central ejection nozzle 321 is disposed in a central region of the plurality of gas distribution parts 310. The extension ejection nozzle 324 extends into a space between the first gas distribution parts 310. The extension path 323 communicates with the central ejection nozzle 321 and the extension ejection nozzle 324 to receive the second processing gas. The first gas distribution parts 310 of this exemplary embodiment are disposed corresponding to the substrates 116, respectively. Thus, the second processing gas may be ejected into a space between the first gas distribution parts 310 to supply the second processing gas into a space between the substrates 116. Thus, the second processing gas that is not cooled may be further supplied onto the substrate 116. As a result, decomposition efficiency of the second processing gas may be improved to increase thin film deposition efficiency.

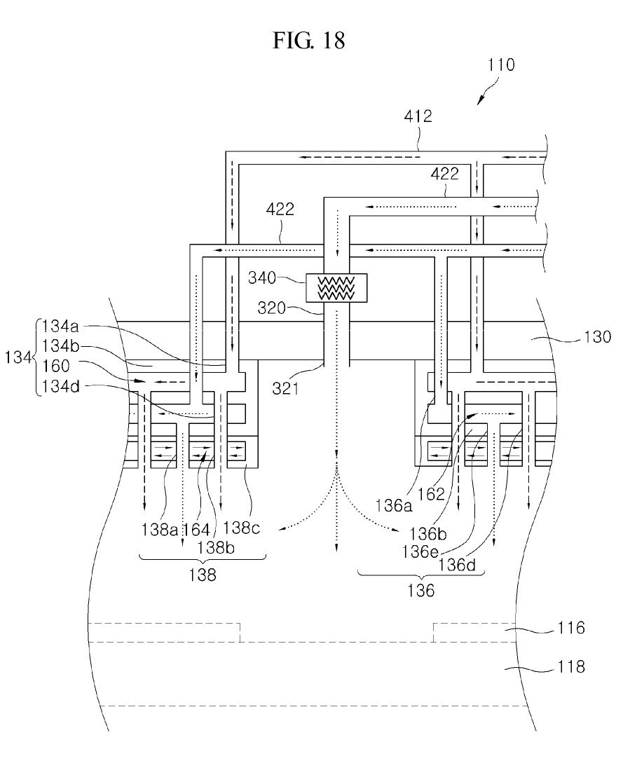

As shown in FIG. 18, an external heating unit 340 for heating the second processing gas supplied into the second gas distribution part 320 may be further disposed outside the second gas distribution part 320. An electrical heating device and an optical heating device may be used as the external heating unit 340. Thus, the second processing gas may be heated to further improve the decomposition efficiency.

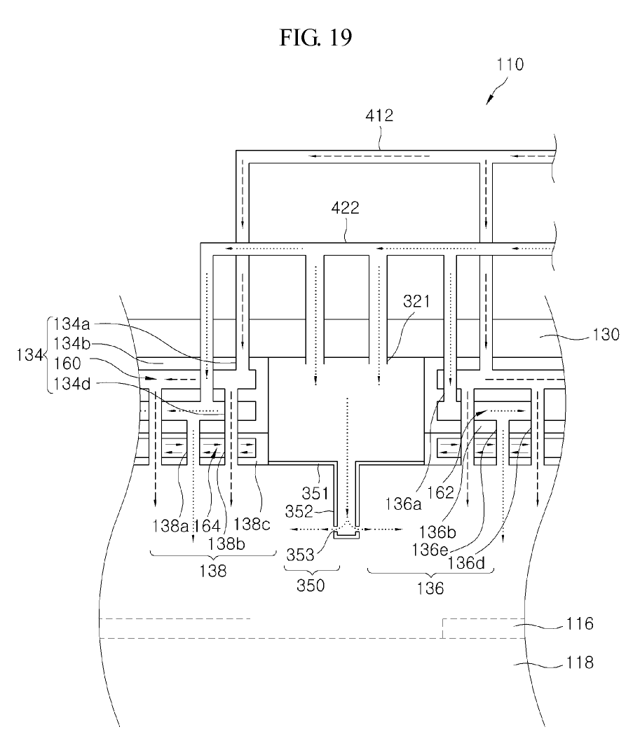

As shown in FIG. 19, the second gas distribution part 320 may include a plurality of central ejection nozzles 321. Thus, the second processing gas may be effectively supplied to the central region of the substrate seat unit 118. Also, the second gas distribution part 320 may further include a path change device 350 ejecting the second processing gas supplied from the second gas distribution part 320 toward the substrates 116. The path change device 350 includes a fixed plate 351, an extension path 352 extending from a central region of the fixed plate 351 toward the substrate seat unit 118, and a path change nozzle 353 disposed at an end of the extension path 352. Here, the fixed plate 351 collects the second processing gas ejected through the second gas distribution part 320. In FIG. 19, a portion of the fixed plate 351 is connected and fixed to the first gas distribution part 310. However, the present disclosure is not limited thereto. For example, the fixed plate 351 may be connected and fixed to the chamber lid 130. The extension path 352 has a rod shape in which an end thereof is closed. Thus, the second processing gas supplied into the extension path 352 is ejected toward the substrates 116 through the path change nozzle 353 disposed around the end of the extension path 352. That is, the second processing gas supplied from the second gas distribution part 320 is ejected in an approximately vertical direction with respect to the substrates 116. Thus, the second processing gas is bumped against the substrate seat unit 118 once, and then, is spread in all directions (i.e., toward the substrates). However, in the modified example of this exemplary embodiment, the second processing gas is supplied to the inside (i.e., the extension path 352) of the path change device 350. Since a lower surface of the extension path 352 is blocked, the second processing gas may be ejected in a direction parallel to the substrates 116 through the path change nozzle 353 disposed at a lateral surface of the extension path 352. Thus, an ejection amount of the second processing gas ejected toward an upper space of the plurality of substrates 116 may be uniformly adjusted.

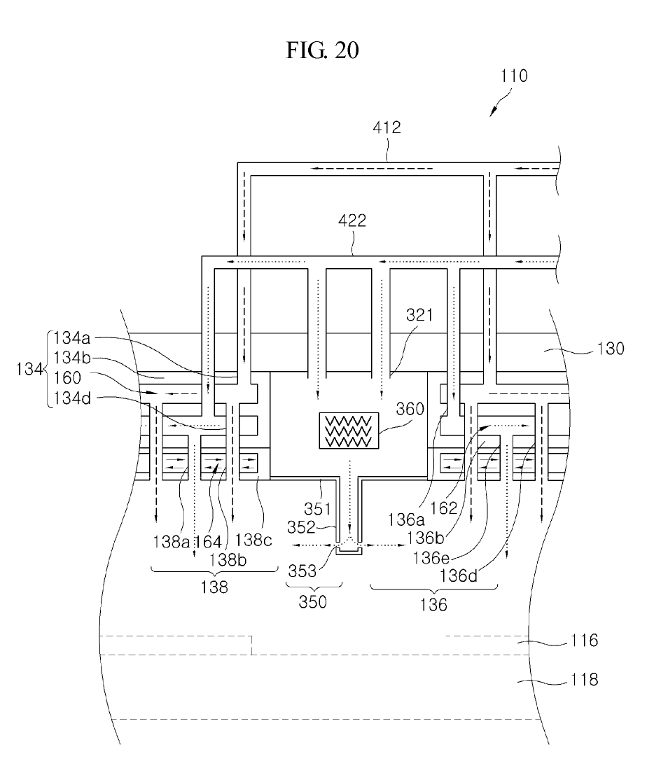

As shown in FIG. 20, an internal heating unit 360 may be further disposed in a lower region of the second gas distribution part 320 of an inner space of the processing chamber 112 to heat the second processing gas supplied from the second gas distribution part 320. That is, the internal heating unit 360 may be disposed in a space between the second gas distribution part 320 and the path change device 350. Here, an electrical heating device and an optical heating device may be used as the internal heating unit 360. Thus, since the second processing gas ejected inside the processing chamber 112 through the second gas distribution part 320 is heated, the decomposition efficiency of the second processing gas may be further improved.

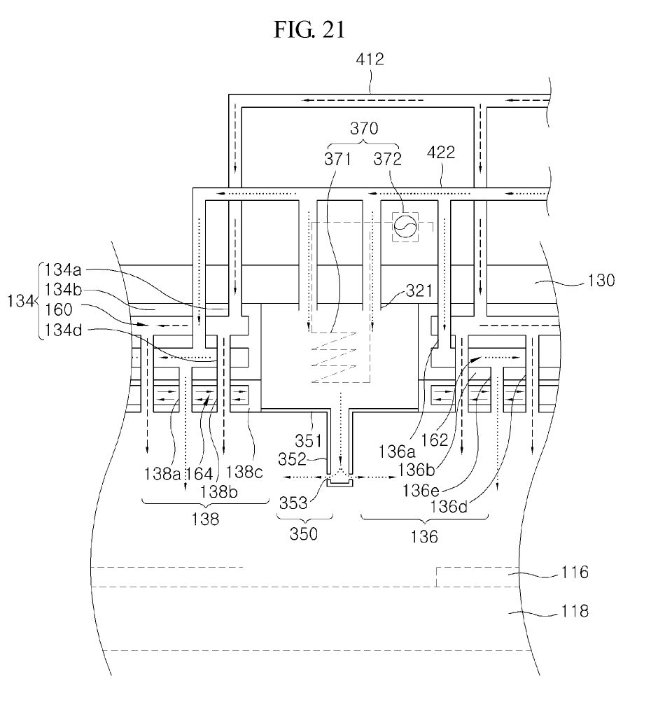

As shown in FIG. 21, a separate plasma generation device 370 generating plasma in a region of the processing chamber 112 below the second gas distribution part 320 may be further provided. The plasma generation device 370 includes an antenna 371 disposed in a space between the second gas distribution part 320 and the path change device 350 and a power supply part 372 supplying a plasma power to the antenna 371. The second processing gas supplied from the second gas distribution part 320 may be ionized by the plasma. Since the second processing gas is ionized, the thin film deposition efficiency may be improved. A capacitive coupled plasma (CCP) method instead of the above-described inductively coupled plasma (ICP) method may be used. For this, a separate electrode may be disposed in a lower region of the second gas distribution part 320. Also, a remote plasma method may be applicable. Thus, a device for changing the second processing gas supplied into the second gas distribution part 320 into plasma may be further provided.

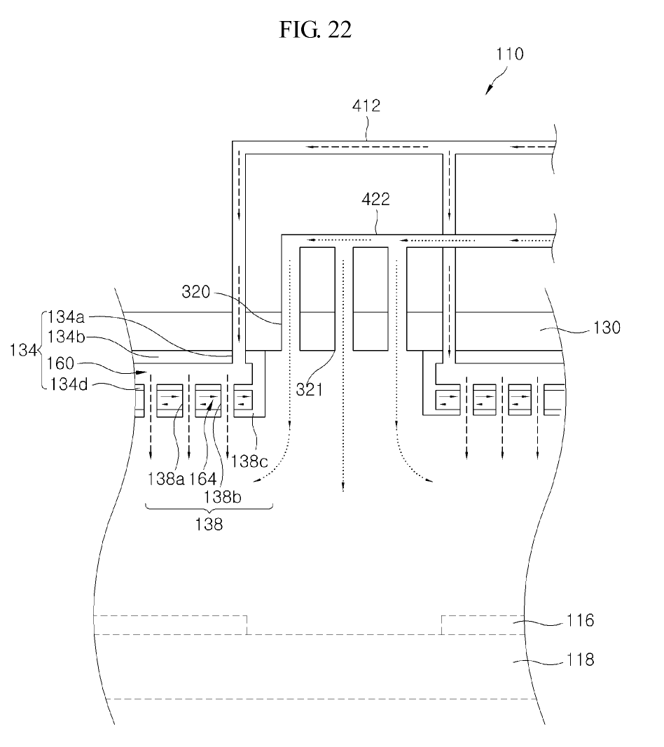

As shown in FIG. 22, the first processing gas having a low decomposition temperature may be ejected into an inner space of the processing chamber 112 through the first gas distribution part 310, and the second processing gas having a high decomposition temperature may be ejected into an inner space of the processing chamber 112 through the second gas distribution part 320. That is, the processing gases may be respectively ejected into the separated spaces to deposit a thin film. Thus, it may prevent the first processing gas having the low decomposition temperature from being decomposed before the first processing gas is ejected into the inner space of the processing chamber 112. Also, it may prevent the second processing gas having the high decomposition temperature from being ejected into the inner space of the processing chamber 112 in a state where the second processing gas is in a cooled state.

Also, although not shown, the first gas distribution part 310 may be integrated with the chamber lid 130. That is, the first gas distribution part 310 may be disposed inside the chamber lid 130. In the above-described descriptions, a semi-batch type apparatus for treating the plurality of substrates was mainly described. However, the present disclosure is not limited thereto. For example, the present disclosure may be applicable to an apparatus for treating a single substrate. In this case, the second gas distribution part ejecting the second processing gas into a peripheral region of the substrate may be disposed.

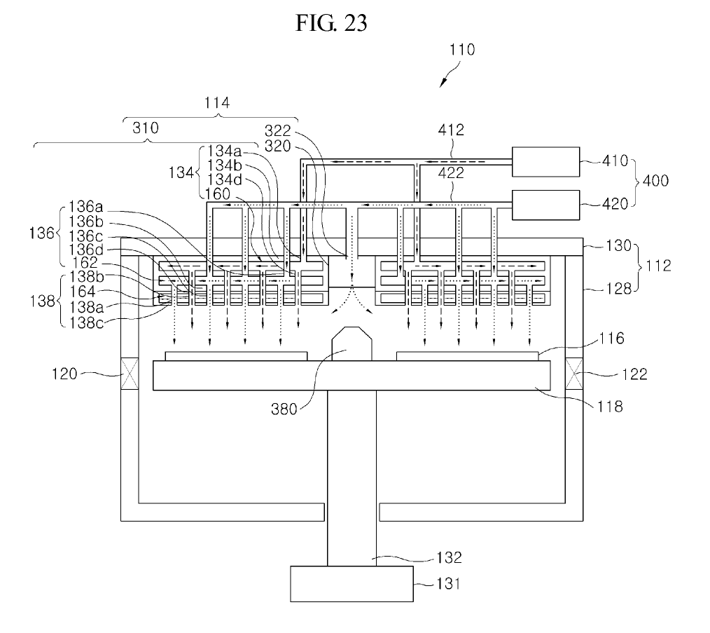

As shown in FIG. 23, an upwardly protruding protrusion 380 may be disposed in the central region of the substrate seat unit 118. Here, the second gas distribution part 320 may have a thickness less than that of the first gas distribution part 310. In this case, when the substrate seat unit 118 ascends, the protrusion 380 may be partially inserted into a lower side of the second gas distribution part 320 between the first gas distribution parts 310. Thus, the second gas distribution part 380 ejects the second processing gas toward the protrusion 380, and the flow direction of the second processing gas is changed by the protrusion 380 to flow toward the substrates 116.

Compounds (GaN, Ga/IN/AlN, TiN, and Ti/AlN) containing two or more elements are deposited on the plurality of substrates at the same time using the substrate treating apparatus of this exemplary embodiment. In accordance with the thin film deposition process, a supply amount of the second processing gas supplied into the second gas distribution part 320 may be varied. For example, the supply of the second processing gas may be fully interrupted by the second gas distribution part 320. This represents that the processing gas may be supplied using only at least one of the first gas distribution part 310 and the second gas distribution part 320. The first gas distribution part 310 and the second gas distribution part 320 in according to the exemplary embodiments may be coupled and fixed to the chamber lid 130 except that the first gas distribution parts 310 are separated and coupled from/to each other.

The substrate treating apparatus including the gas distribution apparatus in accordance with the exemplary embodiments has the following effects.

In three gas distribution plates in which two processing gases are independently ejected at the same time, since a space in which the refrigerant flows is defined in the gas distribution plate including the nozzle for ejecting the processing gas onto the substrate, it may prevent particles from being generated by the decomposition of the processing gases and prevent the gas distribution apparatus from being thermally deformed. The two gas distribution plates are manufactured using the drilling or sheet metal forming process. Also, since only the gas distribution plate including the nozzle is manufactured using the brazing process, the simplified structure may be realized, and also the manufacturing coat may be reduced.

The temperature meter is disposed on the gas distribution plate including the nozzle to provide a signal by which the processing or substrate treating process are stopped when a temperature of the gas distribution plate increases over a predetermined temperature during the brazing or substrate treating process. Thus, since the processing or substrate treating process is automatically stopped by the signal, limitations occurring during the manufacturing process or substrate treating process may be prevented.

Also, since the processing gas having the high decomposition temperature is ejected into the space between the substrates, a travel time of the processing gas is greater than that of the processing gas in case where the processing gas is directly ejected on the substrates. Thus, the processing gas may be pre-heated within the processing chamber for a longer time to increase the decomposition of the processing gas having the high decomposition temperature, thereby reducing the usage of the processing gas and improving the thin film deposition efficiency.

Also, since the processing gas having the high decomposition temperature in the plurality of processing gases is ejected through a peripheral region of an ejection device except the ejection device having a cooling function, the processing gas having the high decomposition temperature may be ejected into the processing chamber (i.e., substrates) without cooling the processing gas.

Also, since the processing gas having the high decomposition temperature is ejected in the chamber lid region above the central portion of the substrate seat unit on which the plurality of substrates is seated, i.e., a region in which a temperature is relatively high in a gas ejection region, the usage of the processing gas may be reduced and the thin film deposition efficiency may be improved due to the pre-heating of the processing gas.

Also, the separate path change device may be disposed in a region in which the processing gas having high decomposition temperature is ejected to eject the processing gas toward the substrate. Thus, an amount of the processing gas supplied onto the substrate may be uniform.

Also, the second gas distribution part of the gas distribution apparatus may be divided in plurality, and the plurality of second gas distribution parts may be coupled and separated to/from each other. Thus, the large-scaled gas distribution apparatus in accordance with the tendency of the large-scaled processing chamber 112 may be further easily manufactured.

Although the gas distribution apparatus and substrate treating apparatus having the same has(have) been described with reference to the specific embodiments, it(they) is(are) not limited thereto. Therefore, it will be readily understood by those skilled in the art that various modifications and changes can be made thereto without departing from the spirit and scope of the present invention defined by the appended claims.

What is claimed is:

1. A gas distribution apparatus comprising:
a first gas distribution part configured to eject at least two source materials onto a substrate through routes different from each other; and
a second gas distribution part configured to eject a source material having a decomposition temperature greater than an average of decomposition temperatures of the at least two source materials onto the substrate,
wherein the first gas distribution part is divided into at least two sections and disposed such that the second gas distribution part is positioned therebetween; and couplable and separable to/from one another.

2. The gas distribution apparatus of claim 1, wherein the first gas distribution part comprises:
a first gas distribution plate connected to a first gas inlet tube configured to introduce a first processing gas, the first gas distribution plate comprising a plurality of first through holes to pass through the first processing gas;
a second gas distribution plate connected to a second gas inlet tube configured to introduce a second processing gas, the second gas distribution plate comprising a plurality of second through holes aligned with the plurality of first through holes to pass through the first processing gas and a plurality of third through holes passing through the second processing gas; and
a third gas distribution plate comprising: a plurality of first and second nozzles aligned with the plurality of second and third through holes and configured to respectively eject the first and second processing gases; and a space in which a refrigerant flows.

3. The gas distribution apparatus of claim 2, wherein the first gas distribution plate comprises:
a housing comprising a space configured to receive the first processing gas supplied from the first gas inlet tube; and
a distribution unit disposed within the space, the distribution unit being configured to uniformly distribute the first processing gas introduced from the first gas inlet tube.

4. The gas distribution apparatus of claim 3, wherein the distribution unit comprises a plate and a plurality of supply holes defined by punching the plate.

5. The gas distribution apparatus of claim 2, wherein the second gas distribution plate comprises:
a housing connected to the second gas inlet tube, the housing providing a space configured to receive the second processing gas;
a plurality of pillars comprising the plurality of second through holes in the space; and
a plurality of third through holes defined by punching a lower portion of the housing.

6. The gas distribution apparatus of claim 5, wherein the second gas distribution plate comprises:
a partition disposed within the space; and
a buffer space divided by a sidewall of the housing and the partition, the buffer space being configured to receive the second processing gas supplied from the second gas inlet tube.

7. The gas distribution apparatus of claim 6, wherein the second gas distribution plate comprises a supply hole in the partition to supply the second processing gas of the buffer space to the space.

8. The gas distribution apparatus of claim 2, wherein the third gas distribution plate comprises:
a housing in which the plurality of first and second nozzles is disposed, the housing comprising the space in which the refrigerant flows; and
a refrigerant flow tube connected to the housing to supply or discharge the refrigerant.

9. The gas distribution apparatus of claim 8, wherein the housing comprises a sidewall surrounding a lateral surface of the space, an upper plate disposed above the sidewall to communicate with the plurality of first and second nozzles, and a lower plate disposed below the sidewall to communicate with the plurality of first and second nozzles.

10. The gas distribution apparatus of claim 8, wherein the housing comprises a sidewall surrounding a lateral surface of the space and a lower plate in which the plurality of first and second nozzles directly contacting the second gas distribution plate is disposed.

11. The gas distribution apparatus of claim 1, further comprising a temperature meter disposed on at least one of the second gas distribution plate and the third gas distribution plate.

12. The gas distribution apparatus of claim 1, wherein the second gas distribution part is disposed at a central portion of a lower side of a chamber lid, and the at least two first gas distribution parts are disposed below the chamber lid such that the second gas distribution part is positioned therebetween.

13. The gas distribution apparatus of claim 1, wherein at least one of the at least two first gas distribution plates is spaced apart from each other.

14. The gas distribution apparatus of claim 1 or claim 13, further comprising at least one third gas distribution part disposed between the at least two first gas distribution parts to eject a fuzzy gas.

15. The gas distribution apparatus of claim 14, wherein the third gas distribution part ejects the fuzzy gas toward an outer side of the substrate.

16. The gas distribution apparatus of claim 15, wherein protrusions are formed at both lateral surfaces of the at least two first gas distribution parts, and grooves corresponding to the protrusions are formed at both lateral surfaces of the third gas distribution part to insert protrusions into the grooves, thereby coupling the third gas distribution part between the first gas distribution parts.

17. The gas distribution apparatus of claim 14, wherein a temperature detector is disposed below the at least one third gas distribution part.

18. A substrate treating apparatus comprising:
a chamber comprising a reaction space;
a substrate seat unit disposed in the reaction space of the chamber to radially seat a plurality of substrates with respect to a center thereof; and
a gas distribution device comprising a first gas distribution part configured to eject at least two source materials onto a substrate through routes different from each other and a second gas distribution part configured to eject a source material having a decomposition temperature greater than an average of decomposition temperatures of the at least two source materials onto the substrate,
wherein the first gas distribution part is divided into at least two sections, and the divided first gas distribution parts are disposed such that the second gas distribution part is positioned therebetween; and couplable and separable to/from one another.

19. The gas distribution apparatus of claim 18, wherein the chamber comprises a chamber body in which the reaction space is provided and a chamber lid configured to seal the reaction space, and the first and second gas distribution parts are fixed to the chamber lid.

20. The gas distribution apparatus of claim 18, wherein a refrigerant path through which a refrigerant is circulated is disposed in the chamber lid.

21. The gas distribution apparatus of claim 18, wherein the first gas distribution part comprises:
a first gas distribution plate connected to a first gas inlet tube configured to introduce a first processing gas, the first gas distribution plate comprising a plurality of first through holes to pass through the first processing gas;
a second gas distribution plate connected to a second gas inlet tube configured to introduce a second processing gas, the second gas distribution plate comprising a plurality of second through holes aligned with the plurality of first through holes to pass through the first processing gas and a plurality of third through holes passing through the second processing gas; and
a third gas distribution plate comprising a plurality of first and second nozzles aligned with the plurality of second and third through holes and configured to respectively eject the first and second processing gases, and a space in which a refrigerant flows.

22. The gas distribution apparatus of claim 18, wherein the second gas distribution part comprises at least one central injection nozzle disposed in a chamber region corresponding to a central region of the substrate seat unit.

23. The gas distribution apparatus of claim 18, wherein the second gas distribution part comprises:
a central injection nozzle disposed in a central region of the first gas distribution part;
an extension injection nozzle extending into a space between the first gas distribution parts; and
an extension path communicating with the central injection nozzle and the extension injection nozzle.

24. The gas distribution apparatus of claim 18, further comprising a path change device disposed in a lower region of the second gas distribution part to eject a processing gas supplied from the second gas distribution part toward the substrate.

25. The gas distribution apparatus of claim 24, wherein the path change device comprises:
a fixed plate a portion of which is connected to each of the plurality of first gas distribution parts, the fixed plate being disposed at a centre of the plurality of the first gas distribution parts;
an extension path extending from a central region of the fixed plate toward the substrate seat unit; and
a path change nozzle disposed at an end region of the extension path.

26. The gas distribution apparatus of claim 18, further comprising a heating unit configured to heat a processing gas ejected from the second gas distribution part or a plasma generation device configured to ionize the processing gas ejected from the second gas distribution part using plasma.

27. The gas distribution apparatus of claim 18, further comprising a protrusion disposed on the substrate seat unit, the protrusion being inserted into a lower side of the second distribution part between the first gas distribution parts.
